(19) United States
(12) Patent Application Publication
(10) Pub. No.: US 2015/0234281 A1
(43) Pub. Date: Aug. 20, 2015

(54) Blade for Substrate Edge Protection During Photolithography

(71) Applicant: RUDOLPH TECHNOLOGIES, INC., Flanders, NJ (US)

(72) Inventors: Steven D. Gardner, Westford, MA (US); J. Casey Donaher, Westford, MA (US)

(73) Assignee: Rudolph Technologies, Inc., Flanders, NJ (US)

(21) Appl. No.: 14/433,194

(22) PCT Filed: Oct. 2, 2013
(86) PCT No.: PCT/US2013/062958

§ 371 Date: Apr. 2, 2015

Related U.S. Application Data
(60) Provisional application No. 61/733,374, filed on Dec. 4, 2012.
(60) Provisional application No. 61/710,494, filed on Oct. 5, 2012.

(51) Int. Cl. G03F 7/20

(52) U.S. Cl. CPC G03F 7/2026; G03F 7/2022

(57) ABSTRACT

An apparatus protects a portion of a peripheral region (310) of a photoresist-coated surface of a substrate (308) from light exposure. The apparatus includes a blade (502, 512, 522, 532) that can move, or that can move and rotate, and a drive assembly (504, 514, 524, 534) operably coupled to the blade. In response to at least one first drive force generated by the drive assembly, the blade translates, rotates, or translates and rotates, such that the blade is disposed above a portion of the peripheral region. In response to at least one second drive force generated by the drive assembly, the blade translates, rotates, or rotates and translates, such that the blade is not disposed above a portion of the peripheral region. In a step-and-repeat lithographic system, the blade covers a portion of the peripheral region, and the adjacent portion of the substrate is exposed to light.

### CROSS-REFERENCE TO RELATED APPLICATIONS

This application claims the benefit of U.S. Provisional Application No. 61/710,494, filed Oct. 5, 2012, and U.S. Provisional Application No. 61/733,374, filed Dec. 4, 2012, both of which are incorporated herein by reference in their entirety.

### BACKGROUND OF THE INVENTION

The present invention relates generally to photolithography, and more particularly to substrate edge protection during photolithography.

Photolithography is a widely used process in the manufacture of electronic, optoelectronic, and electrical devices; for example, it is used in the processing of semiconductor wafers, liquid-crystal display panels, and printed circuit boards. In photolithography, a substrate is coated with a layer of photoresist. The photoresist is exposed to an image defining the structures to be fabricated on the substrate; the exposed photoresist is then developed.

Two varieties of photoresist are used. In a positive photoresist, the regions of the photoresist that are exposed to light are removed during development, and the regions of the photoresist that are not exposed to light remain after development. In a negative photoresist, the regions of the photoresist that are not exposed to light are removed during development, and the regions of the photoresist that are exposed to light remain after development.

During device manufacturing, devices are often tested on the substrate level. Test probes make electrical contact to test contacts on the peripheral region of the substrate and provide a test path to a test instrument. Typically the entire surface of the substrate, including the peripheral region, is coated with photoresist. If a negative photoresist is used, and if the peripheral region is exposed to light during the imaging process, then a layer of photoresist will remain on the peripheral region after the development process. Since photoresist is an electrical insulator, the peripheral region needs to be protected from light during the imaging process to provide access for the test probes.

A mask can be placed over the substrate which protects the peripheral region from light during the imaging process. The geometry of the mask is fixed and is customized for the size and shape of a specific substrate. For a production facility handling a variety of sizes and shapes of substrates, a large number of masks needs to be fabricated, stocked, and swapped. Furthermore, the mask needs to be placed over the substrate prior to the imaging process and removed from the substrate after the imaging process. This procedure is repeated for each substrate. For high-speed manufacturing, the masking steps can decrease throughput.

### BRIEF SUMMARY OF THE INVENTION

An apparatus protects a portion of a peripheral region of a photoresist-coated surface of a substrate from light exposure. In an embodiment, the apparatus includes a blade that can translate, and a drive assembly operably coupled to the blade. In response to at least one first drive force generated by the drive assembly, the blade translates such that the blade is disposed above a portion of the peripheral region. In response to at least one second drive force generated by the drive assembly, the blade translates such that the blade is not disposed above a portion of the peripheral region.

In another embodiment, the apparatus includes a blade that can translate, rotate, or translate and rotate and a drive assembly operably coupled to the blade. In response to at least one first drive force generated by the drive assembly, the blade translates, rotates, or translates and rotates such that the blade is disposed above a portion of the peripheral region. In response to at least one second drive force generated by the drive assembly, the blade translates, rotates, or translates and rotates such that the blade is not disposed above a portion of the peripheral region.

These and other advantages of the invention will be apparent to those of ordinary skill in the art by reference to the following detailed description and the accompanying drawings.

### BRIEF DESCRIPTION OF THE DRAWINGS

FIG. 1A-FIG. 1D show schematics of a reference Cartesian coordinate system;

FIG. 2A-FIG. 2H show schematics of embodiments of lithographic projection systems;

FIG. 3A-FIG. 3E show examples of substrate geometries;

FIG. 4A-FIG. 4F show a method for substrate edge protection, according to an embodiment of the invention;

FIG. 5A-FIG. 5F show a method for substrate edge protection, according to an embodiment of the invention;

FIG. 6A-FIG. 6H show a method for substrate edge protection, according to an embodiment of the invention;

FIG. 7A-FIG. 7C show approximations of a circle with a polygon;

FIG. 8 shows a geometrical scenario for determining the number of movable blades;

FIG. 9A-FIG. 9D show schematics of a substrate edge protection device with a single movable blade, according to an embodiment of the invention;

FIG. 10A-FIG. 10J show a method for substrate edge protection, according to an embodiment of the invention;

FIG. 11A-FIG. 11G show schematics of a substrate edge protection device with multiple movable blades, according to an embodiment of the invention; and

FIG. 12 shows a schematic of a controller implemented with a computational system.

### DETAILED DESCRIPTION

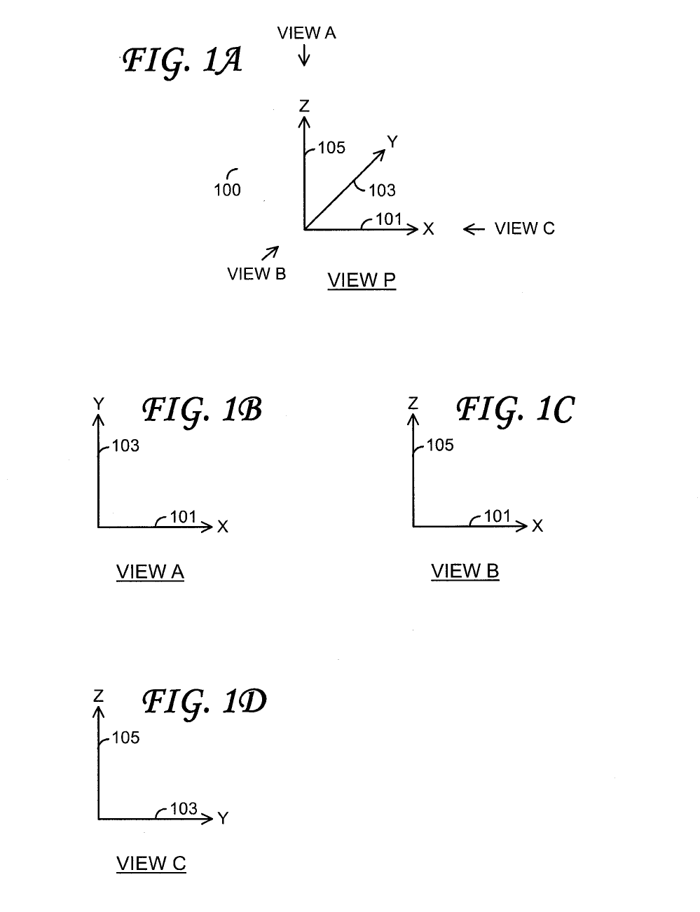

In the descriptions of components and systems below, a three-dimensional (3-D) Cartesian coordinate reference system is used. FIG. 1A shows a perspective view (View P) of the Cartesian coordinate reference system 100, defined by the X-axis 101, the Y-axis 103, and the Z-axis 105. FIG. 1B shows View A, sighted along the −Z axis, of the X-Y plane; FIG. 1C shows View B, sighted along the +Y-axis, of the X-Z plane; and FIG. 1D shows View C, sighted along the −X-axis, of the Y-Z plane. Unless otherwise stated, the origin is arbitrary: in the figures below, reference axes are placed such that they do not interfere with other elements of the figures.

Herein, when geometrical conditions are specified, ideal mathematical conditions are not implied. A geometrical condition is satisfied if it is satisfied within a specified tolerance, which can depend, for example, on available manufacturing tolerances, requirements for specific applications, and trade-offs between performance and cost. The tolerance is specified, for example, by a design engineer. For example, a surface is planar (flat) if it is flat within a specified tolerance; two surfaces are parallel if they are parallel within a specified tolerance; two lines are orthogonal if the angle between them is 90 deg within a specified tolerance; and a circle has a specified out-of-round tolerance.

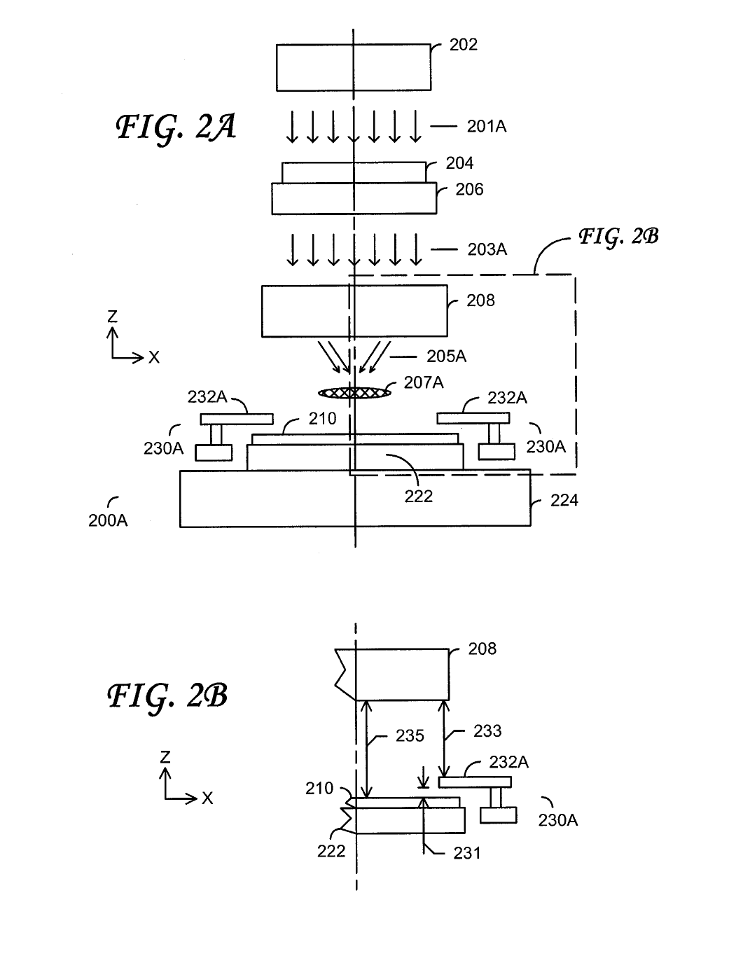

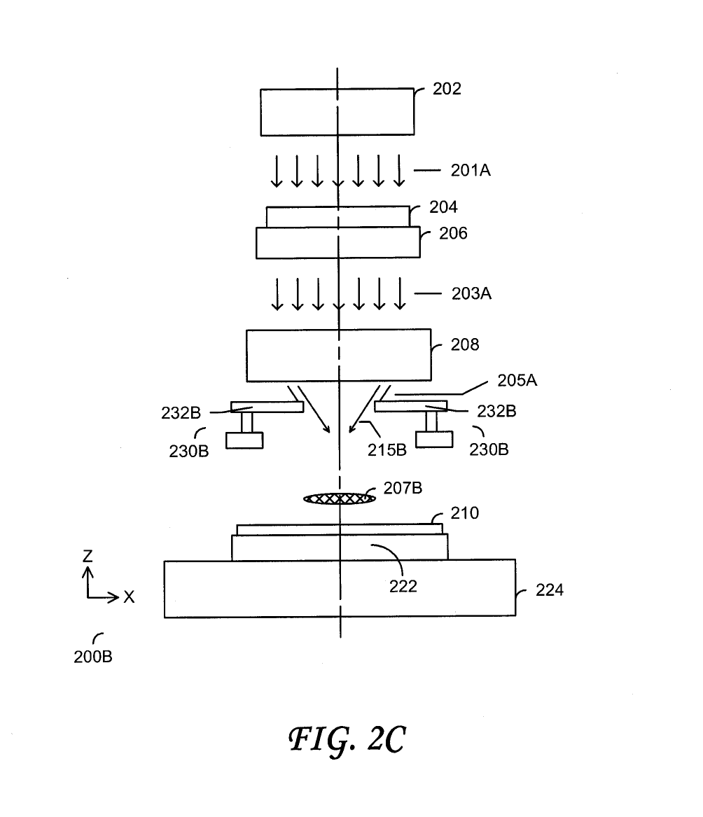

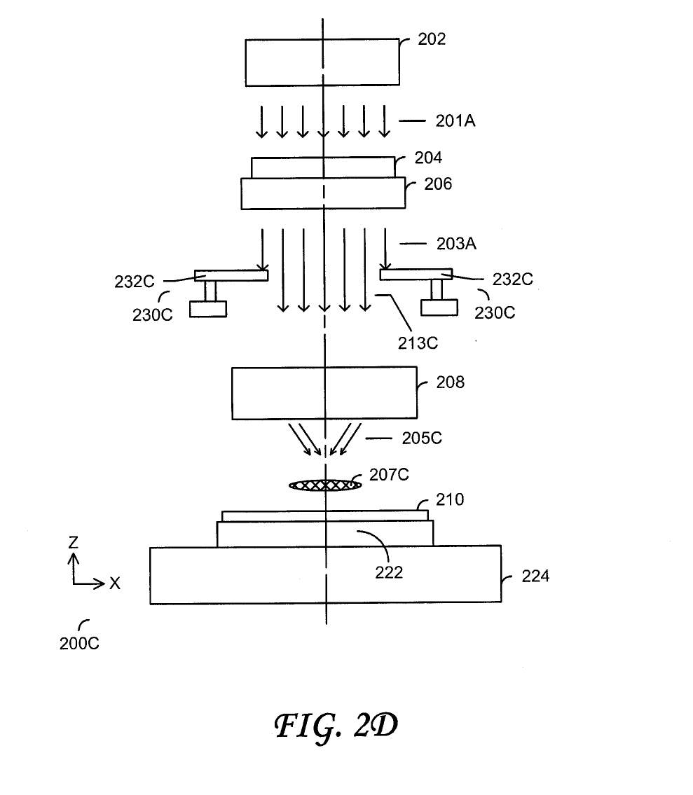

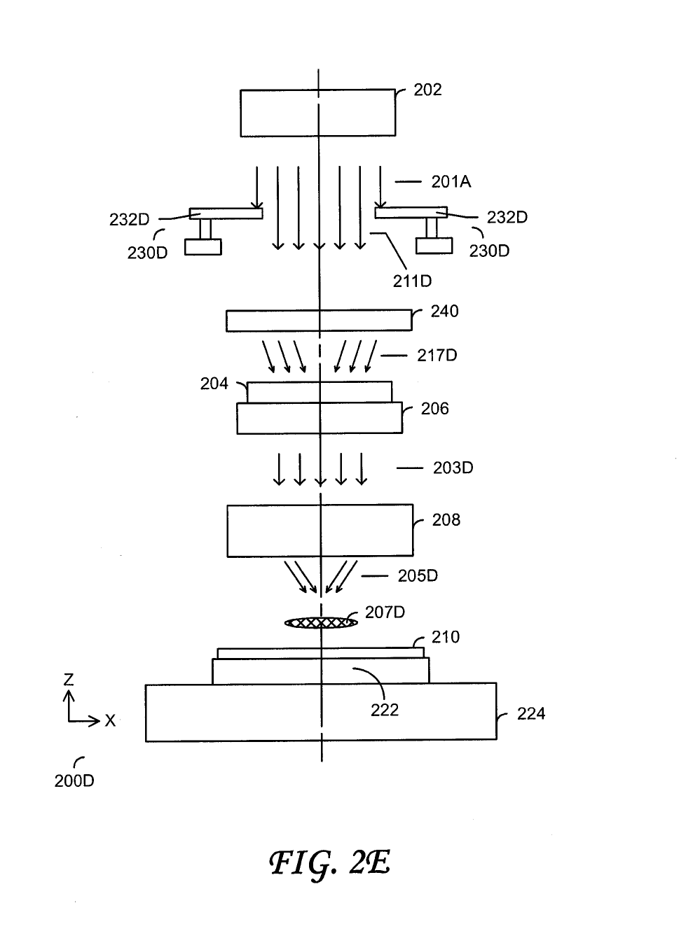

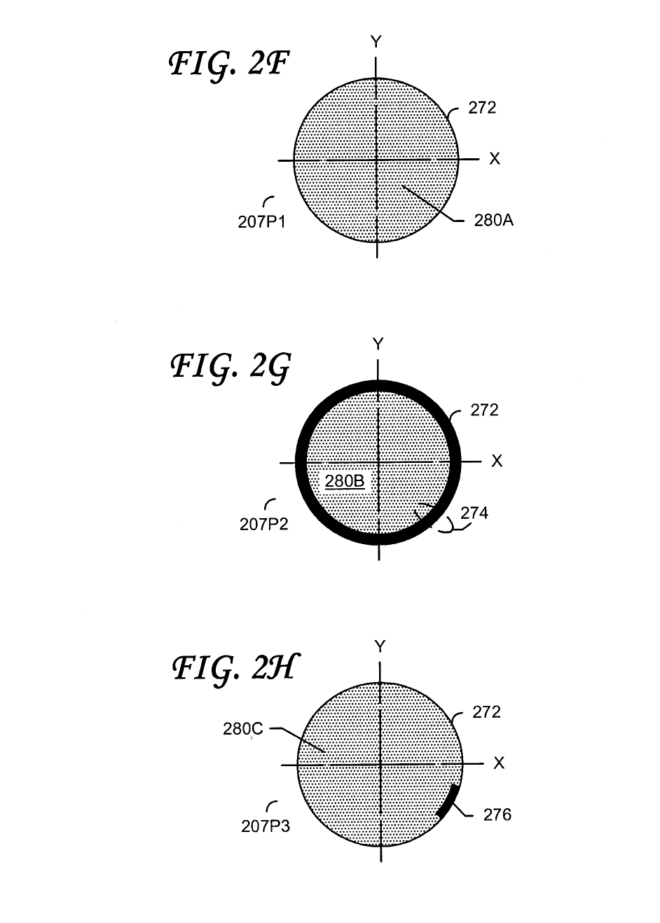

FIG. 2A shows a schematic block diagram of a lithographic projection system 200A. The light source 202 projects the light 201A through the reticle 204, which is supported on the reticle holder 206. The reticle 204 contains a pattern to be imaged. The light 203A transmitted through the reticle 204 is received by the projection system 208, which focusses the light 205A into the image 207A, which is projected onto the surface of the substrate 210 coated with photoresist. Common examples of substrates include semiconductor wafers, liquid-crystal display (LCD) panels, and printed circuit boards (PCBs). The substrate 210 is held by the substrate stage 222, which can move with respect to the platen 224 and the projection system 208. The substrate stage 222 can move along the X-axis and the Y-axis. In general, the substrate stage can also move along the Z-axis and rotate about the Z-axis (theta motion). Some substrate stages are also equipped with tilt adjustments.

The projection system 208 can operate in a flood-illumination mode or in a step-and-repeat mode. In a flood-illumination mode, the entire substrate 210 is exposed to light during the imaging process. In a step-and-repeat mode, light is projected onto only a portion of the substrate: the substrate is moved such that a first position of the substrate is aligned with the projection system, and a first portion of the substrate is exposed to light; the substrate is then moved such that a second position of the substrate is aligned with the projection system, and a second portion of the substrate is exposed to light . . . the process is iterated until all the intended portions of the substrate have been exposed.

As discussed above, in some applications using negative photoresist, the peripheral region of the substrate needs to be protected from light during the imaging process. FIG. 2A shows a substrate edge protection device 230A positioned between the projection system 208 and the substrate 210. Embodiments of the substrate edge protection device 230A are described below.

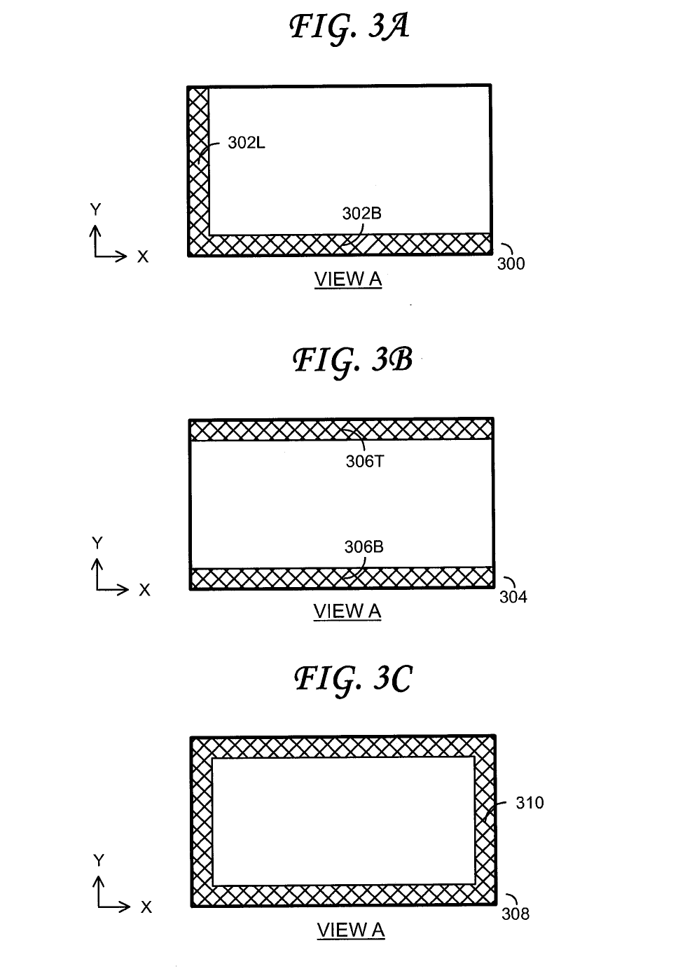

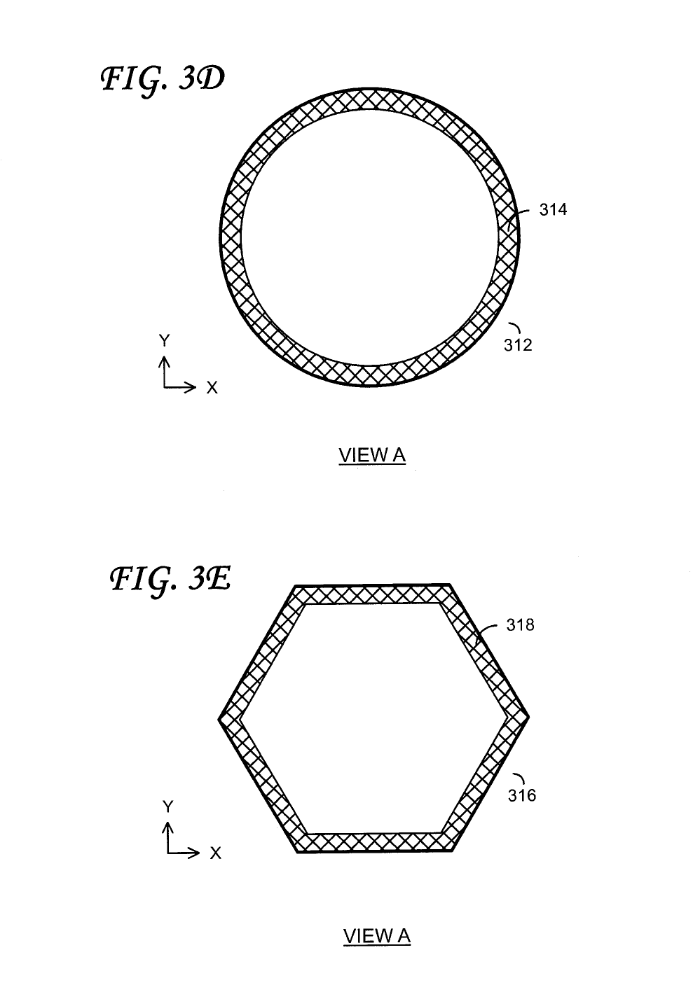

In general, a substrate can have an arbitrary size and shape, and the peripheral region can have an arbitrary size and shape consistent with the size and shape of the substrate. The region of the substrate that is not within the peripheral region is referred to as the interior region of the substrate. Common shapes of substrates are rectangular (for example, for liquid-crystal display panels and printed circuit boards) and circular (for example, for semiconductor wafers). In general, the peripheral region that needs to be protected can comprise a single connected region or multiple disjoint regions. FIG. 3A-FIG. 3E show some specific examples.

FIG. 3A (View A) shows a schematic of a rectangular substrate 300.

The peripheral region that needs to be protected comprises the rectangular region 302L along the left-hand edge and the rectangular region 302B along the bottom edge (two adjacent edges or two orthogonal edges).

FIG. 3B (View A) shows a schematic of a rectangular substrate 304.

The peripheral region that needs to be protected comprises the rectangular region 306T along the top edge and the rectangular region 306B along the bottom edge (two opposite edges or two parallel edges).

FIG. 3C (View A) shows a schematic of a rectangular substrate 308.

The peripheral region that needs to be protected comprises the rectangular annular region 310.

FIG. 3D (View A) shows a schematic of a circular substrate 312.

The peripheral region that needs to be protected comprises the circular annular region 314.

FIG. 3E (View A) shows a schematic of a hexangular substrate 316.

The peripheral region that needs to be protected comprises the hexangular annular region 318.

Refer to FIG. 2A. In embodiments of the substrate edge protection device 230A described below, substrate edge protection is provided by one or more movable blades 232A positioned closely above the surface of the substrate 210. Refer to FIG. 2B, which shows a close-up view of the portion of FIG. 2A indicated by the dashed rectangle in FIG. 2A. Important design parameters are the clearance 231 (spacing along the Z-axis) between the bottom of the one or more movable blades 232A and the surface of the substrate 210, the clearance 233 between the top of the one or more movable blades 232A and the bottom of the projection system 208, and the clearance 235 between the surface of the substrate 210 and the bottom of the projection system 208.

The one or more movable blades are fabricated from a material opaque to the wavelength of light used for imaging. The one or more movable blades are first retracted to allow clearance for insertion of the substrate; the one or more movable blades are then deployed to protect the specified portion of the peripheral region of the surface of the photoresist-coated substrate from light exposure during the imaging process; the imaging process is completed; and the one or more movable blades are then retracted to allow clearance for removal of the substrate. Embodiments of substrate edge protection devices accommodate different sizes and shapes of substrates and different sizes and shapes of peripheral regions.

The movable blades can be moved via different drive assemblies. As a first example, each movable blade is independently driven by an individual motor. As a second example, the entire set of movable blades is mechanically coupled and driven in unison by a single motor. As a third example, different subsets of movable blades are mechanically coupled. For each subset, the movable blades are driven in unison by a single motor. Operation of a motor is controlled by a controller, which can, for example, be a computer-based controller. Sources of motive force other than a motor can be used in a drive assembly (for example, piezoelectric or pneumatic actuators).

Some embodiments of the substrate edge protection device 230A are mounted on the substrate stage (such as substrate stage 222 in FIG. 2A) and move in unison with the substrate. Other embodiments of substrate edge protection devices are mounted off the substrate stage and move independently of the substrate. The separate stage, for example, can be attached to the projection system 208 (FIG. 2A) or to a separate support infrastructure (not shown). For example, a substrate edge protection device can be mounted on a separate stage whose motion can be coordinated with the motion of the substrate stage. As discussed above, the bottom surfaces of the movable blades and the top surface of the substrate are vertically separated. The clearance 231 (FIG. 2B) is specified to be large enough to avoid unintentional contact between the movable blades and the substrate and small enough to avoid excessive leakage of the light beam to the peripheral region.

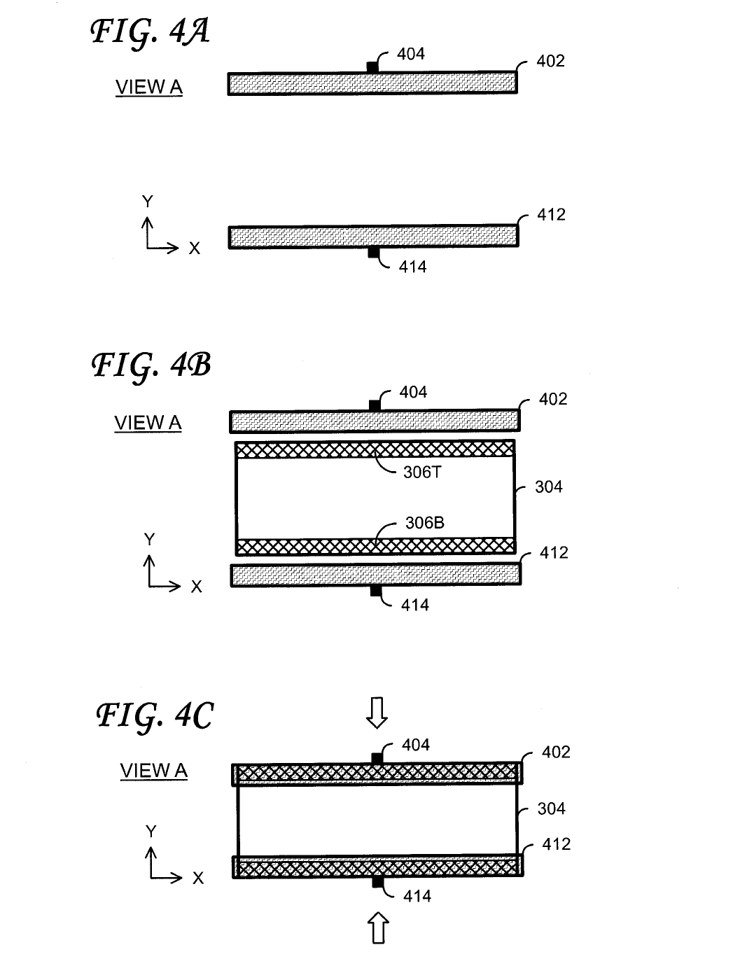

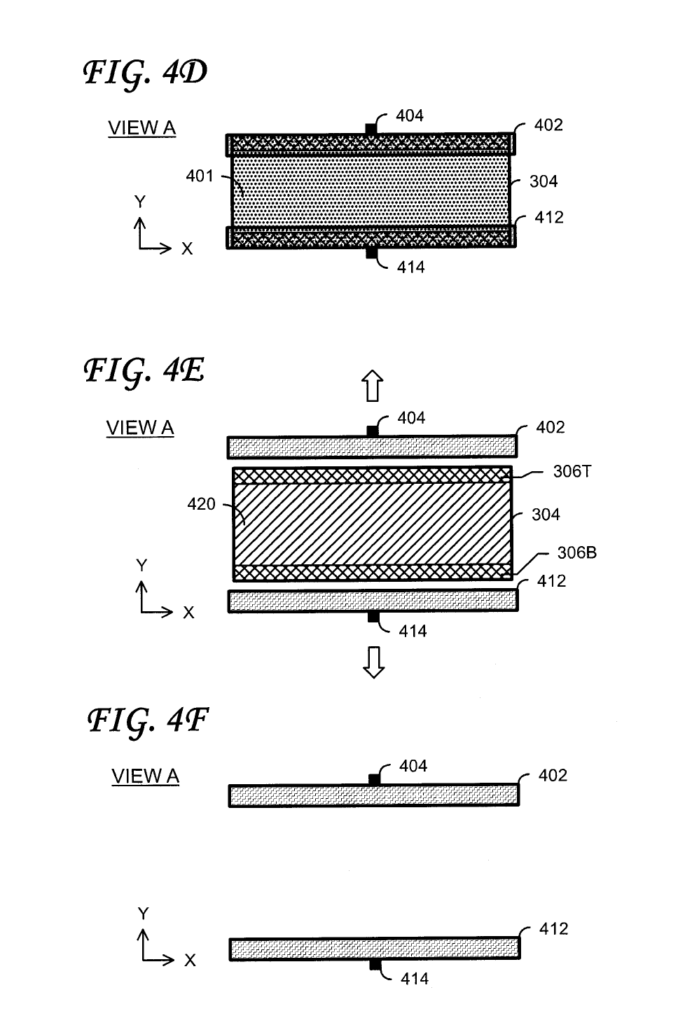

FIG. 4A-FIG. 4F (View A) show a processing sequence for the substrate 304 (FIG. 3B). FIG. 4A shows an embodiment of a substrate edge protection device in the retracted mode. For simplicity, the drive mechanism, mounting configuration, and controller are not shown. The substrate edge protection device includes a first movable blade 402 with an attached arm 404 and a second movable blade 412 with an attached arm 414. In FIG. 4B, the substrate 304 is inserted between the movable blades. In FIG. 4C, the movable blades are deployed: the movable blade 402 is moved along the −Y direction to cover the rectangular region 306T; and the movable blade 412 is moved along the +Y direction to cover the rectangular region 306B. After the movable blades have been deployed, the substrate edge protection device is in the deployed mode.

In FIG. 4D, the substrate 304 is exposed to the light 401 (indicated by dotted hatching). The rectangular region 306T is protected from light exposure by the movable blade 402; and the rectangular region 306B is protected from light exposure by the movable blade 412. As discussed above, the substrate can be exposed via flood illumination or via a step-and-repeat process.

In FIG. 4E, the movable blade 402 and the movable blade 412 are retracted. The region 420 (indicated by diagonal hatching) represents the region of the substrate that has been exposed to light. In step 4F, the substrate 304 is removed, and the substrate edge protection device is ready to receive a new substrate.

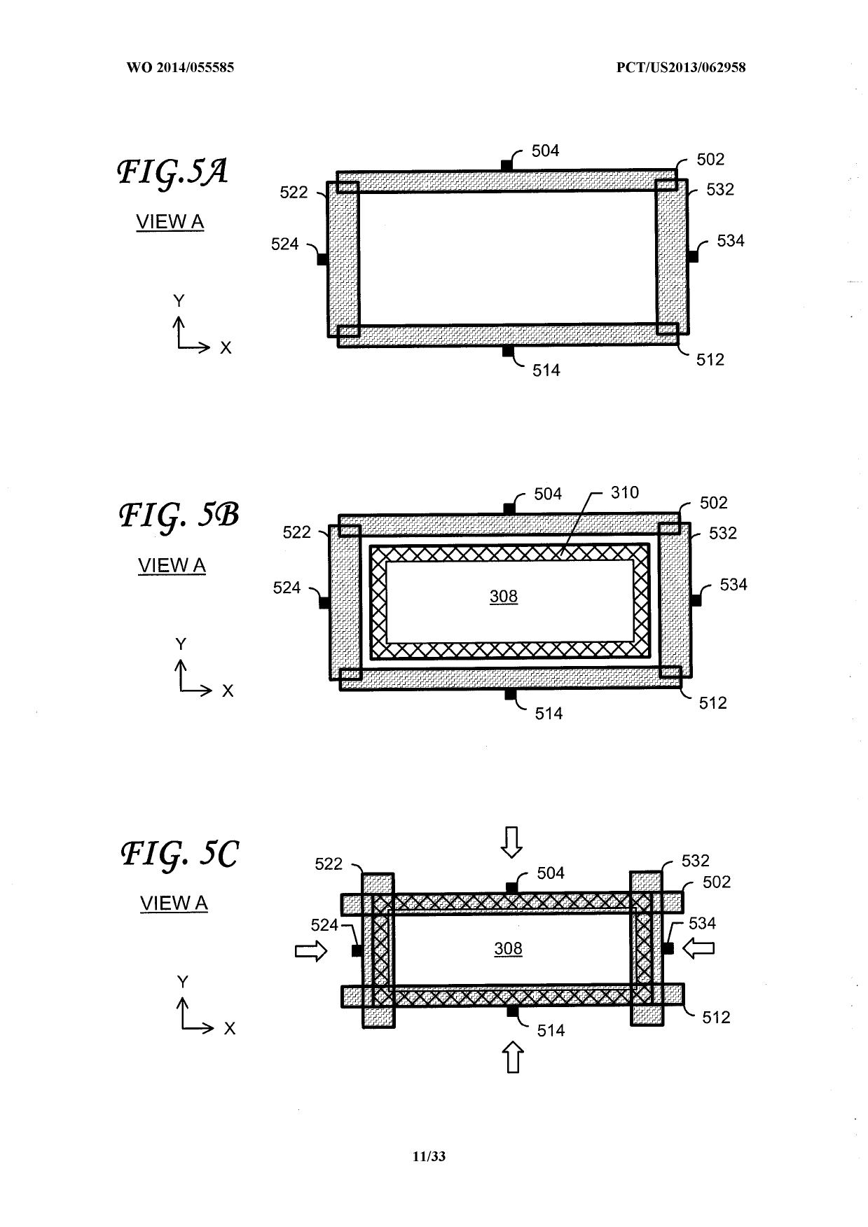

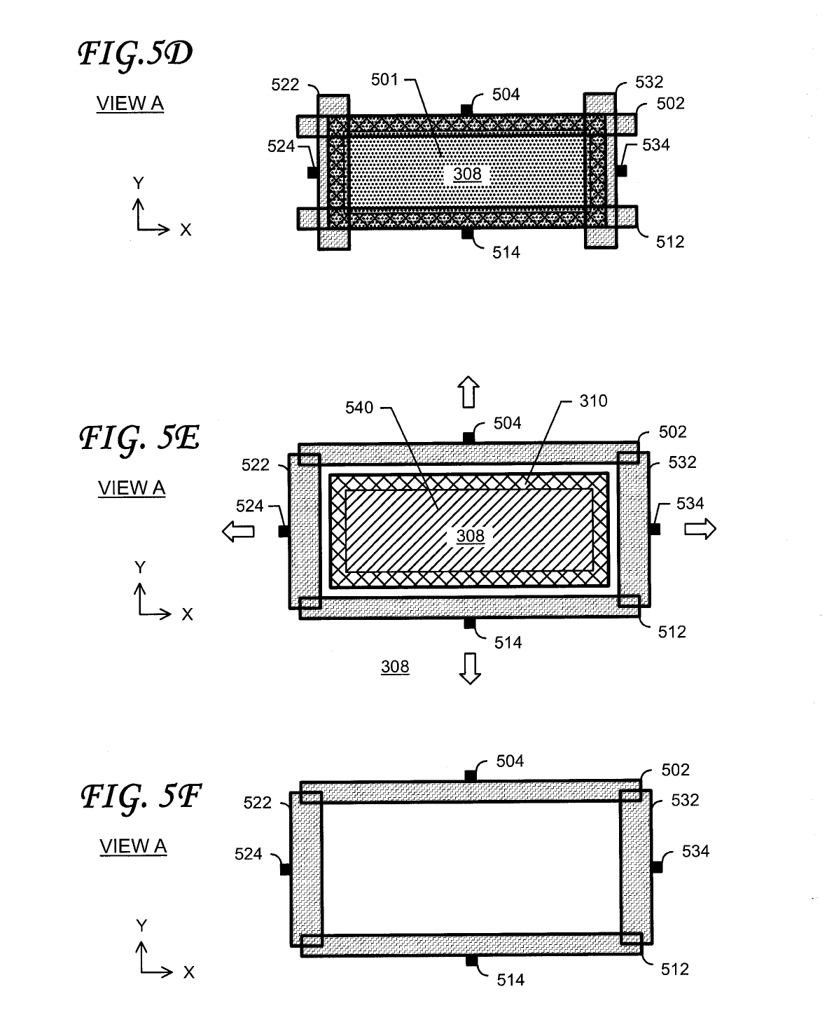

FIG. 5A-FIG. 5F (View A) show a processing sequence for the substrate 308 (FIG. 3C). FIG. 5A shows an embodiment of a substrate edge protection device in the retracted mode. The substrate edge protection device includes a first movable blade 502 with an attached arm 504, a second movable blade 512 with an attached arm 514, a third movable blade 522 with an attached arm 524, and a fourth movable blade 532 with an attached arm 534. In FIG. 5B, the substrate 308 is inserted between the movable blades. In FIG. 5C, the movable blades are deployed to cover the peripheral region 310. The movable blade 502 is moved along the −Y direction; the movable blade 512 is moved along the +Y direction; the movable blade 522 is moved along the +X direction; and the movable blade 532 is moved along the −X direction.

In FIG. 5D, the substrate 308 is exposed to the light 501 (indicated by dotted hatching). The peripheral region 310 is protected from light exposure by the movable blades. In FIG. 5E, the movable blades are retracted. The region 540 (indicated by diagonal hatching) represents the region of the substrate that has been exposed to light. In FIG. 5F, the substrate 308 is removed, and the substrate edge protection device is ready to receive a new substrate.

A processing sequence similar to that described above in reference to FIG. 5A-FIG. 5F can be used for the substrate 300 (FIG. 3A). Only two orthogonal movable blades are used. For example, the movable blade 522 and the movable blade 512 are used to protect the rectangular region 302L and the rectangular region 302B, respectively.

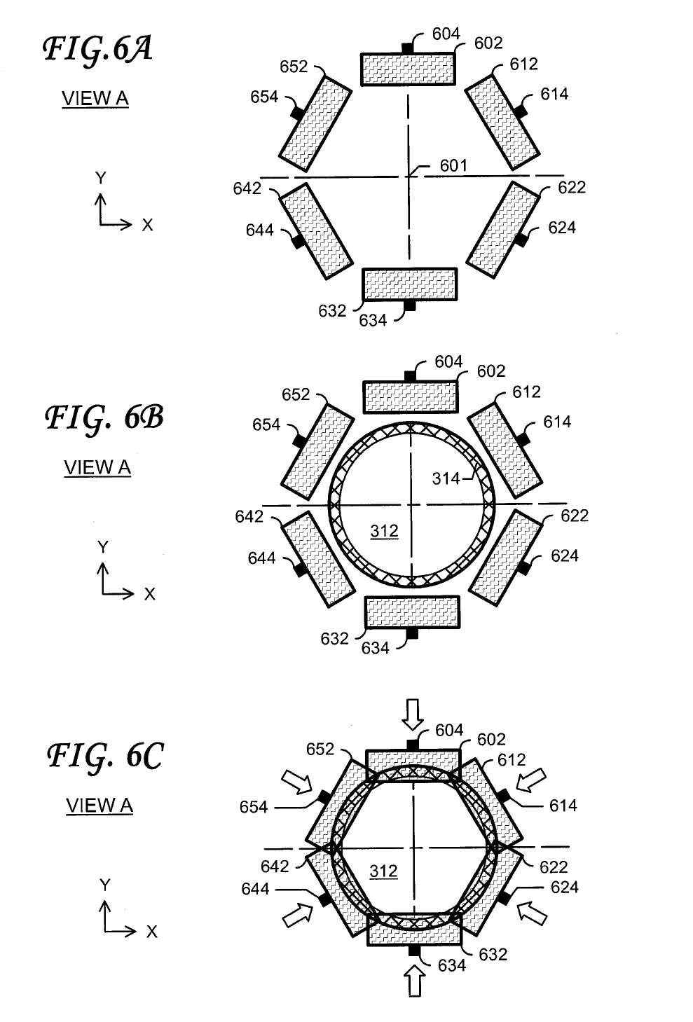

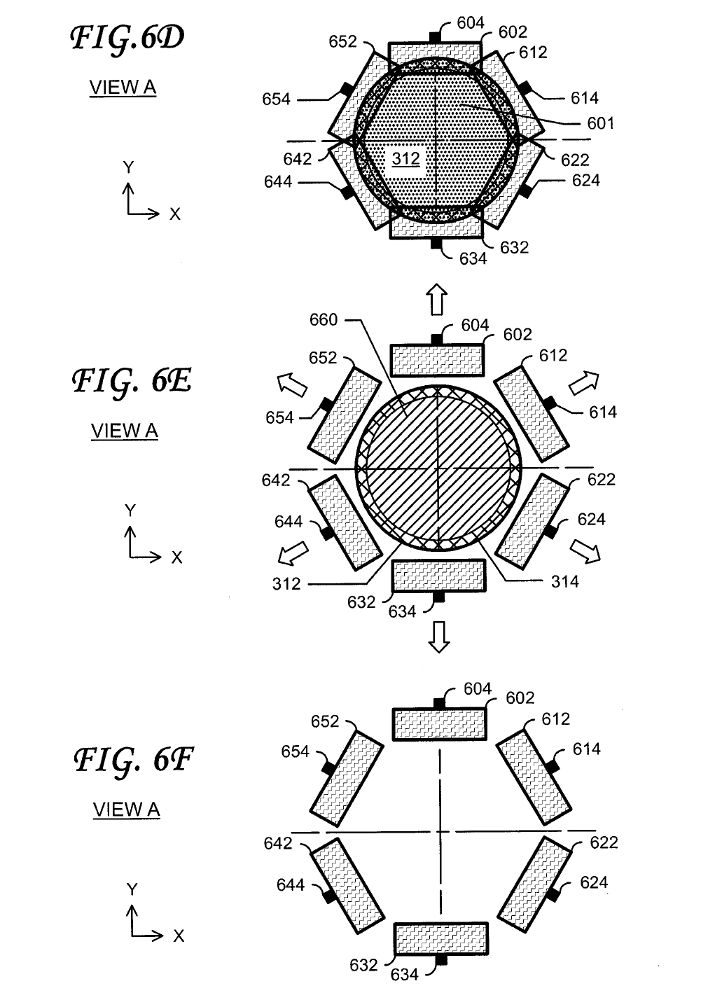

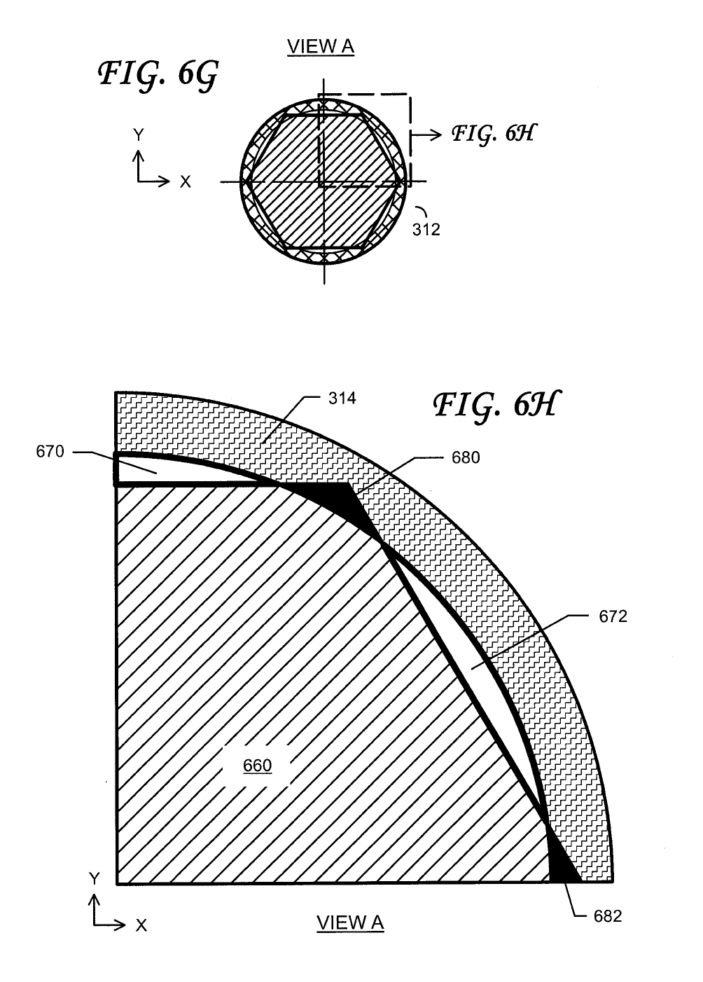

FIG. 6A-FIG. 6F (View A) show a processing sequence for the substrate 312 (FIG. 3D). FIG. 6A shows an embodiment of a substrate edge protection device in the retracted mode. The substrate edge protection device includes a first movable blade 602 with an attached arm 604, a second movable blade 612 with an attached arm 614, a third movable blade 622 with an attached arm 624, a fourth movable blade 632 with an attached arm 634, a fifth movable blade 642 with an attached arm 644, and a sixth movable blade 652 with an attached arm 654. The movable blades are azimuthally arranged about an axis parallel to the Z-axis passing through the center point 601.

In FIG. 6B, the substrate 312 is inserted between the movable blades. In FIG. 6C, the movable blades are deployed to cover the peripheral region 314. The movable blades are moved radially inward.

In FIG. 6D, the substrate 312 is exposed to the light 601 (indicated by dotted hatching). The peripheral region 314 is protected from light exposure by the movable blades. In FIG. 6E, the movable blades are retracted. The region 660 (indicated by diagonal hatching) represents the region of the substrate that has been exposed to light. In FIG. 6F, the substrate 312 is removed, and the substrate edge protection device is ready to receive a new substrate.

FIG. 6G and FIG. 6H show potential problems using a limited number of blades to cover a circular annular ring. FIG. 6G shows the substrate 312 after light exposure. FIG. 6H shows a close-up view of the portion of FIG. 6G indicated by the dashed rectangle in FIG. 6G. Shown are a portion of the peripheral region 314 that needs to be protected from light exposure and a portion of the region 660 exposed to light. Region 670 and region 672 (indicated by white fill) represent portions of regions that should have been exposed to light but were instead covered by the movable blades. Region 680 and region 682 (indicated by black fill) represent portions of the peripheral region that need to be protected from light exposure but were instead left uncovered by the movable blades.

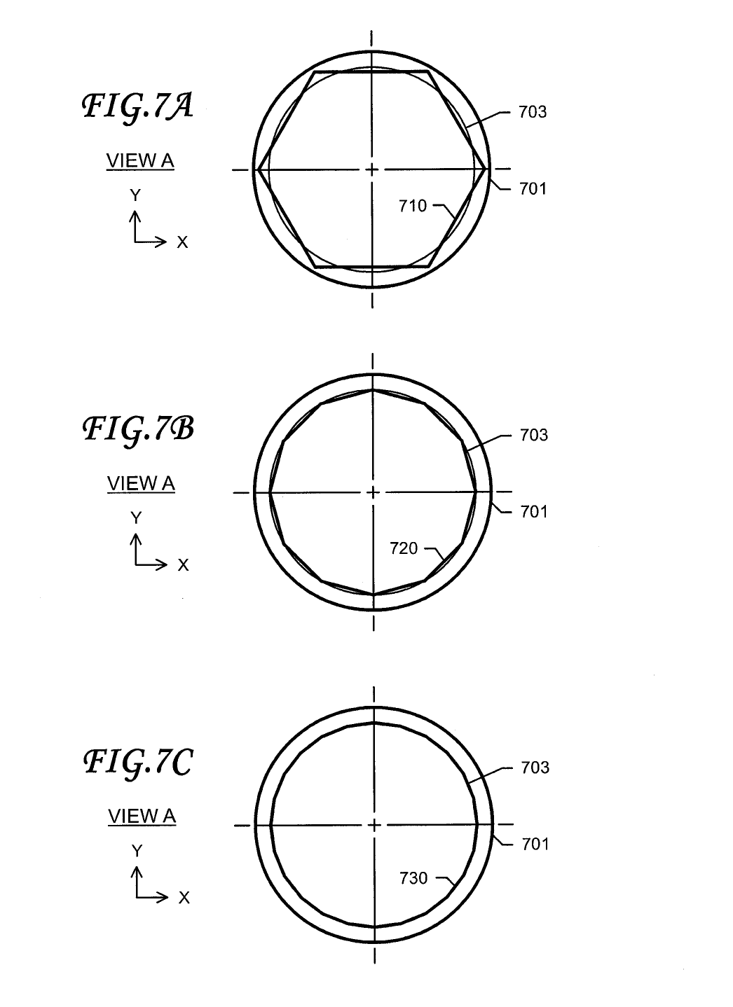

To provide more accurate coverage of a circular annular ring, the number of movable blades can be increased. Refer to FIG. 7A-FIG. 7C (View A). In each figure are shown the reference circle 701, which represents the outer periphery of a substrate, and the reference circle 703, which represents the inner periphery of the substrate. The region between the inner periphery and the outer periphery represents the peripheral region that needs to be protected from light exposure.

FIG. 7A shows an approximation of a circle with a 6-sided regular polygon 710; FIG. 7B shows an approximation of a circle with a 12-sided regular polygon 720; and FIG. 7C shows an approximation of a circle with a 24-sided regular polygon 730. The number of required blades depends on a number of factors, including the range of the radius of the outer periphery, the range of the radius of the inner periphery, acceptable design tolerance, and trade-off between the number of blades and the complexity and cost of manufacture.

Note that, for simplicity, blade edges have been shown as straight line segments. When the peripheral region has a periphery defined by straight line segments (such as for a rectangular substrate), then blade edges with straight line segments are optimal. When the peripheral region has a periphery defined by a circle (such as for a circular substrate), the blade edges can have other geometries; for example, arcs of circles. The radius of the arc can be chosen, for example, as the radius of the circle in the middle of the range of the radius of the inner periphery. In general, depending on the geometry of the peripheral region to be protected, the shape of the blade edge can be curvilinear (a specified path comprising straight line segments, curves, or combinations of straight line segments and curves); in general, the dimensions and shape of each blade edge can be the same or can be different.

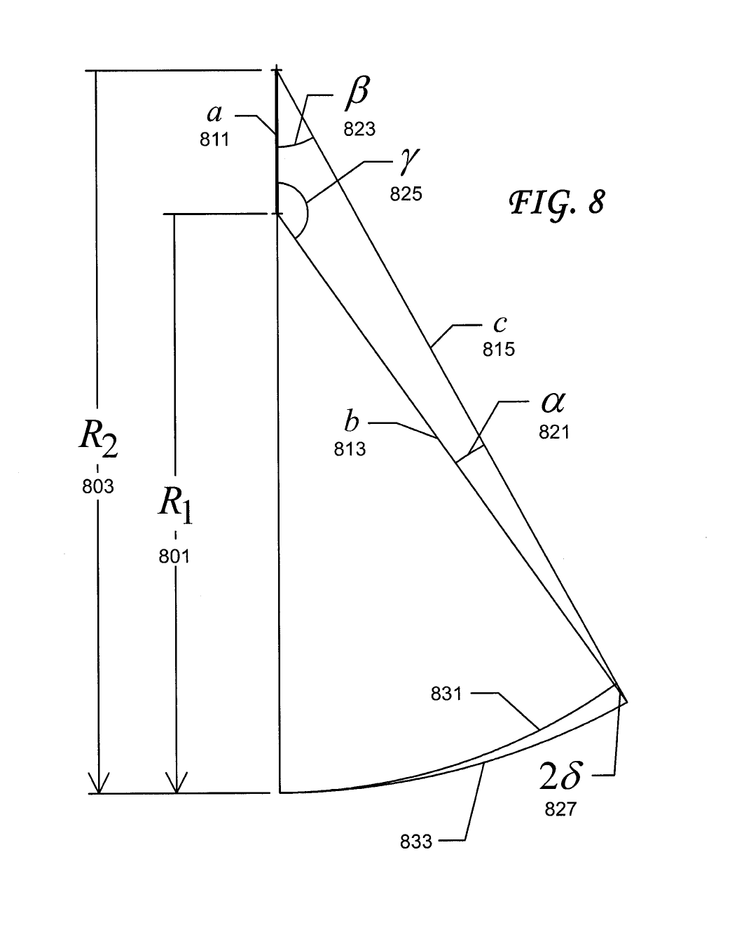

FIG. 8 shows a geometrical schematic used in a method for calculating the required number of blades to protect the peripheral region of circular substrates within a range of radii (that is, a single substrate edge protection device can be used for circular substrates with different sizes). The minimum masking radius is R₁ 801; and the maximum masking radius is R₂ 803. Shown are the reference arc 831 with radius R₁ and the reference arc 833 with radius R₂. Refer to the reference triangle formed by the sides a 811, b 813, and c 815. The included angles are α 821, β 823, and γ 825, as shown. The allowed error due to mismatch is specified as ±δ; the total error range is 2δ 827.

From FIG. 8, the following relationships hold:

a=R₂−R₁,

b=R₁+2δ,

c=R₂.

### From the Law of Cosines:

b²=a²+c²−2ac cos β.

It then follows that:

$$β = {cos}^{- 1} [ \frac{{a}^{2} - {b}^{2} + {c}^{2}}{2 ac} ] .$$

The maximum arc segment to satisfy the allowed mismatch is 2β, and the minimum required number of blades N is given by

$$N = \frac{360}{2 β} = \frac{180}{β} ( deg ) , \\ or$$

$$N = \frac{2 π}{2 β} = \frac{π}{β} ( rad ) .$$

As one specific example, with R₁=145 mm, R₂=165 mm, and δ=0.1 mm, the results are given by β=7.6 deg, and N=24.

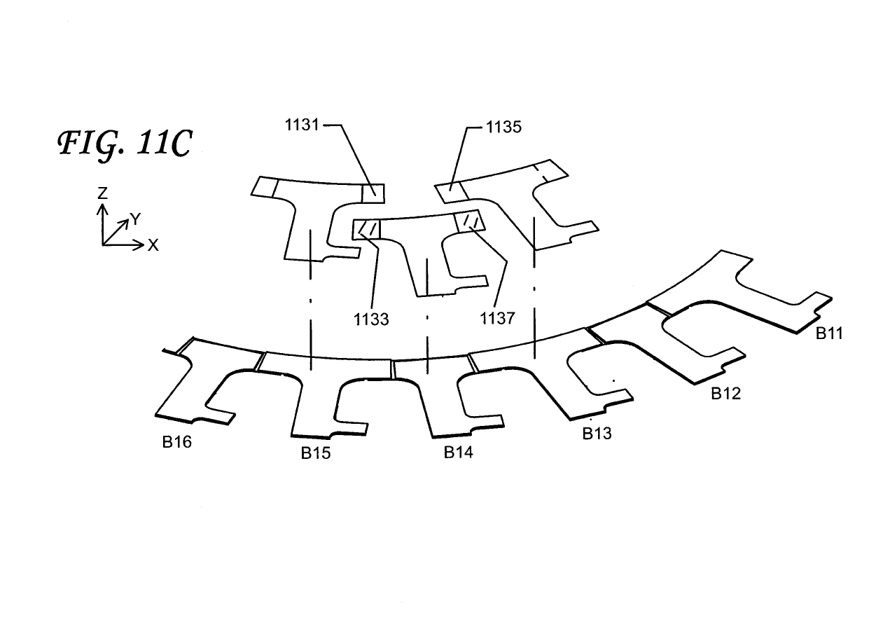

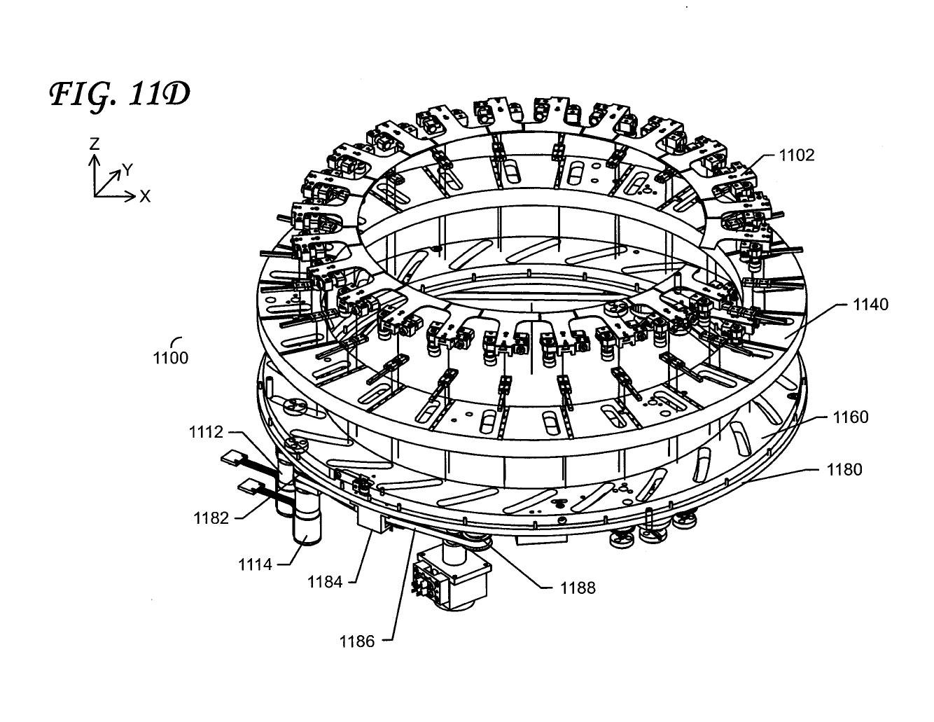

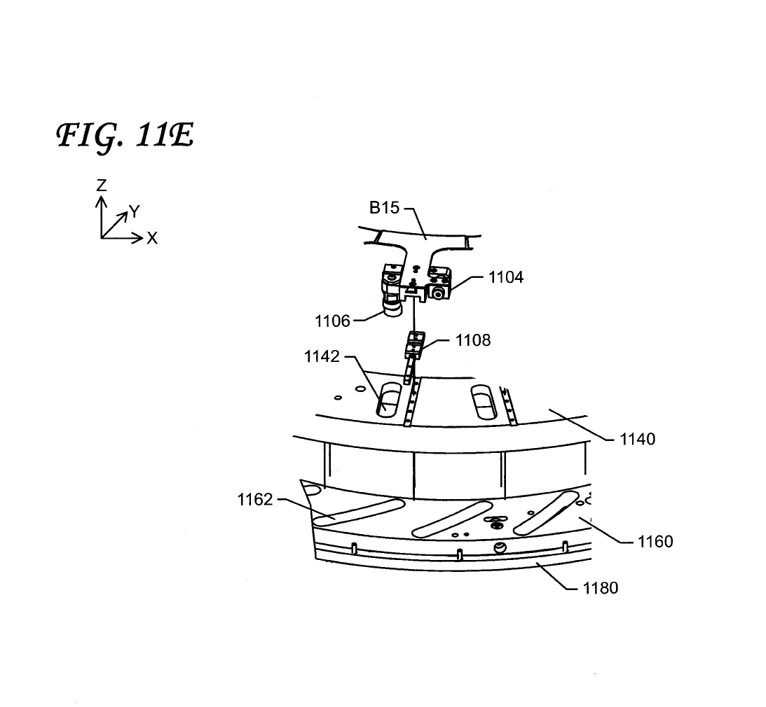

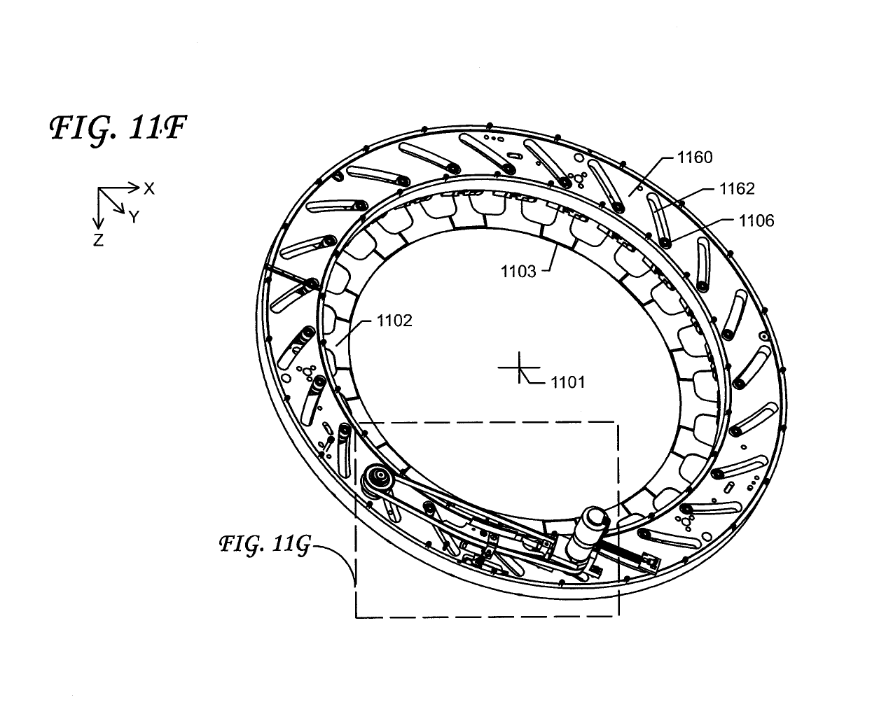

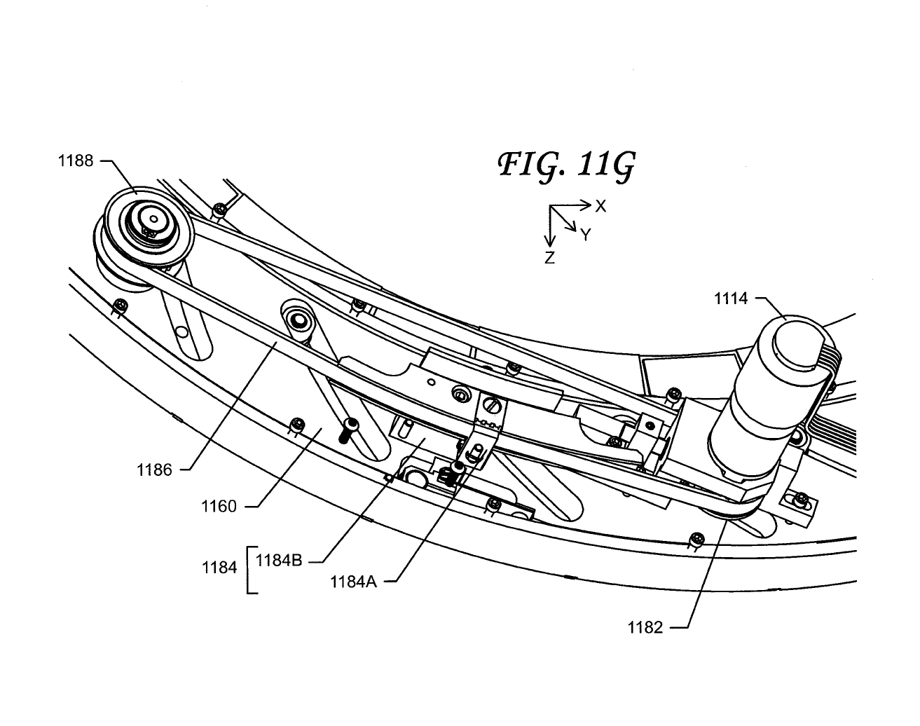

FIG. 11A (View P) shows a schematic of the substrate edge protection device 1100, which is configured to accommodate a circular substrate. In one embodiment, the substrate edge protection device 1100 is mounted on the substrate stage 222 (FIG. 2A). As the substrate stage 222 moves, the substrate edge protection device 1100 automatically maintains its alignment with the substrate. In another embodiment, the substrate edge protection device 1100 is mounted on a separate stage, which can be attached, for example, to the projection system 208 or a separate support infrastructure (not shown). Movements of the substrate and the substrate edge protection device are coordinated to maintain alignment between the substrate edge protection device and the substrate.

The substrate edge protection device 1100 includes a set of movable blades 1102; in the example shown, there are 24 movable blades, labelled B1-B24. Each movable blade can move along a radial direction. In FIG. 11A, the movable blades are shown in the retracted mode. During deployment, the movable blades move radially inward towards the center point 1101. The reference circle 1103 shows the deployed positions of the blade edges. FIG. 11B (perspective view) shows the set of movable blades 1102 in the deployed mode.

Also shown in FIG. 11A and FIG. 11B are two drive motors, referenced as the drive motor 1112 (used for height adjustment) and the drive motor 1114 (used to move the movable blades in and out). The drive motor 1112 is used for height adjustment (along the Z-axis) of the substrate edge protection device 1100 with respect to the substrate. As discussed above in reference to FIG. 2B, the clearance 231 between the bottom of the movable blades and the surface of the substrate is an important design parameter. In an embodiment, the bottom of the movable blades and the surface of the substrate are parallel; in other embodiments, the bottom of the movable blades and the surface of the substrate are not parallel.

In an embodiment, the substrate edge protection device 1100 is supported on adjustable feet (not shown) that can translate along the Z-axis. The adjustable feet are driven by the drive motor 1112, which is controlled by a controller (not shown); the controller can be a computer-based controller. To accommodate substrates of different thicknesses, the substrate edge protection device 1100 can first be raised sufficiently to eliminate unintentional contact between the movable blades and the surface of the substrate and then lowered to the desired height to minimize light leakage under the edges of the movable blades. In particular, with semiconductor wafers, contact can lead to damage, including edge chipping; the adjustable height capability reduces the chances for unintentional contact.

To eliminate light leakage between the movable blades, adjacent movable blades overlap. Refer to FIG. 11C, which shows a close-up view of the movable blades B11-B16. The movable blades B13-B15 are also shown in exploded view. The bottom surface of the region 1131 on B15 overlaps with the top surface of the region 1133 on B14. Similarly, the bottom surface of the region 1135 on B13 overlaps with the top surface of the region 1137 on B13.

FIG. 11D shows an exploded view of the substrate edge protection device 1100. There are four primary layers stacked along the Z-axis. The first (top) layer includes the set of movable blades 1102. The second layer includes the guide plate 1140. The third layer includes the cam plate 1160. The fourth (bottom) layer includes the base plate 1160. Additional details of bearings and support structures are not shown.

The guide plate 1140 and the base plate 1180 are fixed with respect to each other. A cam mechanism is used to convert rotary motion to linear motion. The cam plate 1160 rotates about the Z-axis with respect to the guide plate 1140 and the base plate 1180. Rotation of the cam plate 1160 causes the set of movable blades 1102 to move radially in and out along the X-Y plane with respect to the guide plate 1140. Further details are discussed below.

Operation of each movable blade is similar. FIG. 11E shows a close-up view of the assembly for one representative movable blade (the movable blade B15). The movable blade B15 is attached to the mounting block 1104. Also attached to the mounting block 1104 are the rotary bearing 1106 and the linear bearing 1108. The rotary bearing 1106 passes through the clearance slot 1142 in the guide plate 1140 and sits in the cam slot 1162 in the cam plate 1160. The linear bearing 1108 is attached to the guide plate 1140.

The linear bearing 1108 allows the movable blade B15 to translate in and out along a radial direction on the X-Y plane (refer back to FIG. 11A and FIG. 11B). The drive force is provided by the rotary bearing 1106 sitting in the cam slot 1162. Refer to FIG. 11F, which shows a bottom view of the cam plate 1160; the base plate 1180 is not shown. The rotary bearing 1106 is sitting inside the cam slot 1162.

The cam plate 1160 can be rotated about the Z-axis relative to the guide plate 1140. As the cam plate 1160 rotates, the cam slot 1162 exerts force against the rotary bearing 1106, which in turn transfers force to the mounting block 1104 and the linear bearing 1108. The net force is along the radial direction. Depending on the direction of rotation of the cam plate 1160, the movable blade B15 moves radially in or out. All of the movable blades are similarly coupled to the guide plate 1140 and the cam plate 1160. Rotation of the cam plate 1160, therefore, causes the entire set of movable blades to translate in unison in and out along a radial direction. In the terminology of cam drive systems, the cam slot serves as the cam, the rotary bearing and the mounting block serve as the follower, and the linear bearing serves as the guide.

Details of the cam drive system are shown in FIG. 11D and FIG. 11G. FIG. 11G shows a close-up view of the portion of FIG. 11F indicated by the dashed rectangle in FIG. 11F. Refer to FIG. 11D. The cam plate 1160 is rotated by the drive motor 1114 via a belt-and-pulley system. The drive motor 1114 is attached to the base plate 1180. The pulley 1182 is coupled to the drive shaft of the drive motor 1114. The pulley 1188 is coupled to a separate shaft attached to the base plate 1180. In FIG. 11G, the base plate 1180 has been removed to show the bottom side of the cam plate 1160; and the drive motor 1114 and the pulley 1188 are shown as floating over the cam plate 1160.

The drive belt 1186 couples the pulley 1182 to the pulley 1188. Rotation of the drive shaft of the drive motor 1114 causes the drive belt 1186 to move between the pulley 1182 and the pulley 1188. The coupler 1184 (also referred to as a radial flag assembly) couples the drive belt 1186 to the cam plate 1160. In FIG. 11G, the portion of the coupler 1184 that couples to the drive belt 1186 is referenced as 1184A; and the portion of the coupler 1184 that couples to the cam plate 1160 is referenced as 1184B. Drive force from the drive motor 1114 is transmitted to the drive belt 1186 via the pulley 1182 and the pulley 1188. The drive belt 1186, in turn, transmits the drive force to the cam plate 1160 via the coupler 1184.

Cam drive systems can also be used to move the movable blades shown in FIG. 4A-FIG. 4F, FIG. 5A-FIG. 5F, and FIG. 6A-FIG. 6F. In FIG. 4A-FIG. 4F and FIG. 5A-FIG. 5F, a single movable blade is shown to protect each edge of a rectangular substrate. In other embodiments, multiple movable blades can be used to protect each edge. Multiple movable blades can be advantageous, for example, if the dimension of an edge is large, since one long movable blade can require additional supports to prevent sagging.

The drive motor is controlled by a controller, which can be a computer-based controller. The computer-based controller can synchronize operation of the substrate edge protection device with the overall operation of the lithographic projection system 200A (FIG. 2A): for example, to perform a process similar to the one previously described in reference to FIG. 6A-FIG. 6F. An example of a computer-based controller is described below.

Other drive mechanisms can be used to drive the movable blades. For example, each specific movable blade can be independently driven by its own corresponding specific drive motor, and the operation of all the drive motors can be synchronized by a controller.

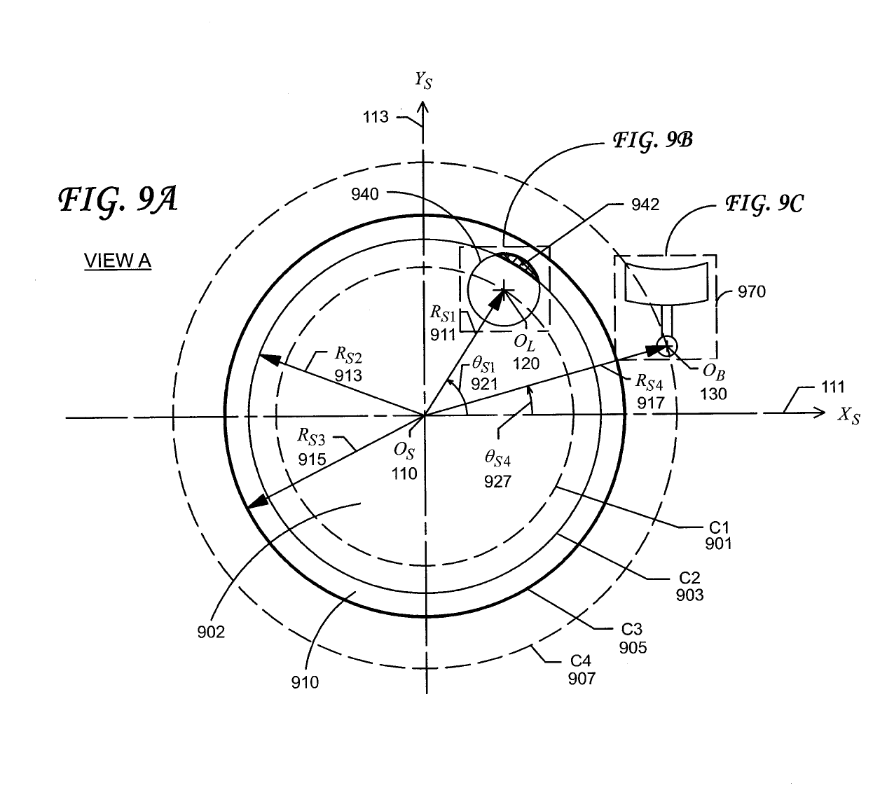

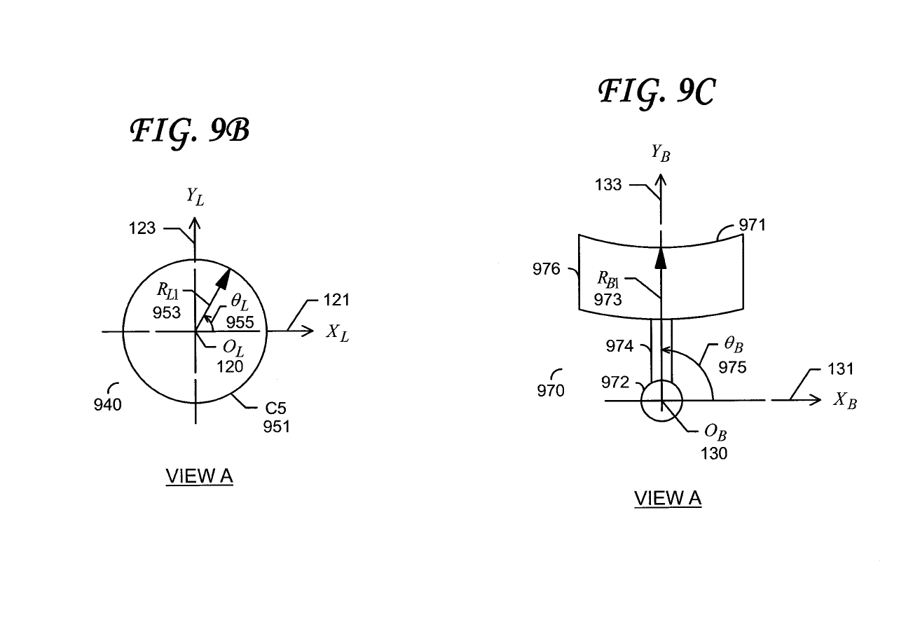

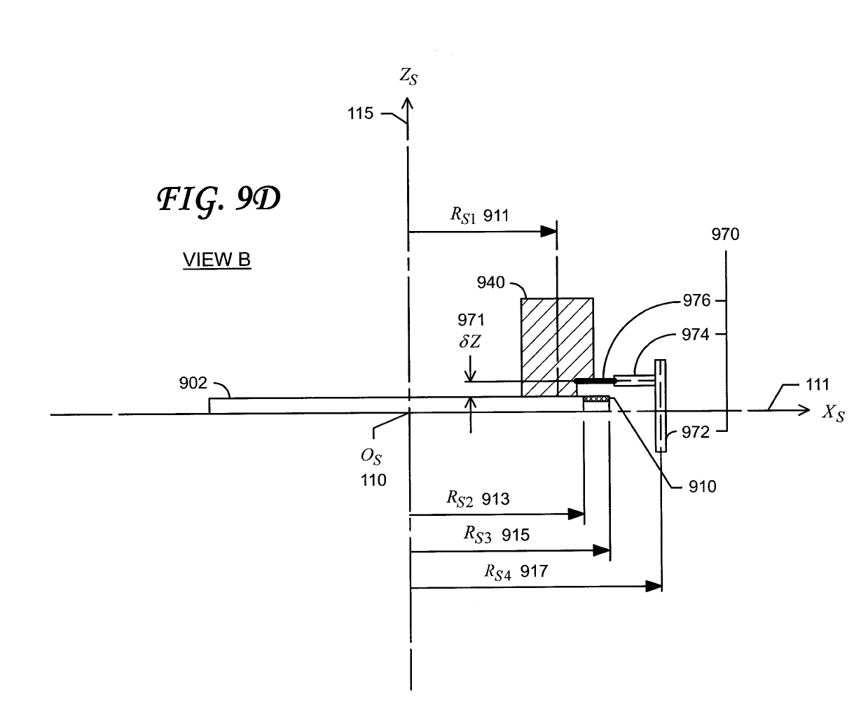

In an embodiment, a single movable blade is used for substrate edge protection with step-and-repeat lithographic systems. FIG. 9A-FIG. 9D show schematics of the geometrical layout. A circular substrate is shown as an example; however, arbitrary shapes of substrates can be accommodated. Several coordinate systems are defined. Refer to FIG. 9A and FIG. 9D. The substrate reference Cartesian coordinate system has the origin O_{S} 110 positioned at the center of the substrate 902; the axes are referenced as the X_{S}-axis 111, the Y_{S}-axis 113, and the Z_{S}-axis 115. Polar coordinates in the X_{S}-Y_{S} plane are specified by (R_{S},θ_{S}), where R_{S} is the radius measured from the origin O_{S}, and θ_{S} is the polar angle measured about the Z_{S}-axis counter-clockwise from the X_{S}-axis.

Refer to FIG. 9A. The outer periphery of the substrate 902 is represented by the circle C3 905, with a radius R_{S3} 915; and the inner periphery of the substrate 902 is represented by the circle C2 903, with a radius R_{S2} 913. The peripheral region 910 is bounded by the circle C2 and the circle C3. The light beam 940 is represented by a circle with the center point O_{L} 120. The polar coordinates of O_{L} with respect to O_{S} are (R_{S1} 911, θ_{S1} 921). The circle C1 901 represents the path of O_{L} with respect to O_{S} when the light beam 940 is closest to the peripheral region 910.

Refer to FIG. 9B. The light beam reference Cartesian coordinate system has the origin O_{L} 120 positioned at the center of the light beam 940; the axes are referenced as the X_{L}-axis 121 and the Y_{L}-axis 123; the Z_{L}-axis, not shown, is orthogonal to the X_{L}-Y_{L} plane. The X_{L}-Y_{L} plane is parallel to the X_{S}-Y₅ plane. Polar coordinates in the X_{L}-Y_{L} plane are specified by (R_{L},θ_{L}), where R_{L} is the radius measured from the origin O_{L}, and θ_{L} is the polar angle measured about the Z_{L}-axis counter-clockwise from the X_{L}-axis. In FIG. 9B, the radius of the light beam 940 is referenced as R_{L1} 953; a representative polar angle is shown as θ_{L} 955.

Refer to FIG. 9A. The movable blade assembly 970 has a pivot axis (see below) centered at the center point O_{B} 130. The polar coordinates of O_{B} with respect to O_{S} are (R_{S4} 917, θ_{S4} 927). The circle C4 907 represents the path of O_{B} with respect to O₅ as the movable blade assembly travels around the substrate. In general, the movable blade assembly can be positioned at various positions adjacent to the outer periphery of the substrate, at a specified distance from the outer periphery of the substrate.

Refer to FIG. 9C. The blade reference Cartesian coordinate system has the origin O_{B} 130 positioned at the center of the post 972; the axes are referenced as the X_{B}-axis 131 and the Y_{B}-axis 133; the Z_{B}-axis, not shown, is orthogonal to the X_{B}-Y_{B} plane. The X_{B}-Y_{B} plane is parallel to the X_{S}-Y_{S} plane. Polar coordinates in the X_{B}-Y_{B} plane are specified by (R_{B},θ_{B}), where R_{B} is the radius measured from the origin O_{B}, and θ_{B} is the polar angle measured about the Z_{B}-axis counter-clockwise from the X_{B}-axis.

The movable blade assembly 970 includes the movable blade 976 with a blade edge 971; the blade edge 971, as shown, has the geometry of a circular arc. In general, the geometry of the blade edge can be curvilinear to conform to various substrate geometries. The movable blade 976 is coupled by the arm 974 to the post 972 (the movable blade can also be coupled directly to the post without an arm). Refer to FIG. 9D (View B). The plane of the movable blade 976 is parallel to the X_{S}-Y_{S} plane; the longitudinal axis of the arm 974 is parallel to the X_{S}-Y_{S} plane; and the longitudinal axis of the post 972 is parallel to the Z_{S}-axis. The post 972 rotates about its longitudinal axis. In some embodiments, the plane of the movable blade 976 is not parallel to the X_{S}-Y_{S} plane.

Refer to FIG. 9C. The radius measured from O_{B} to the center of the blade edge 971 is referenced as R_{B1} 973; the polar angle between the X_{B}-axis and the longitudinal axis of the arm 974 is referenced as θ_{B} 975. The post 972 pivots about its longitudinal axis (parallel to the Z_{S}-axis), thereby varying the polar angle θ_{B} 975.

Refer to FIG. 9D. When the movable blade 976 is deployed, it covers a portion of the peripheral region 910 from exposure to the light beam 940 (for simplicity, the light beam 940 is represented by a cylinder; in practice, the light rays converge at an angle above the movable blade and diverge at an angle below the movable blade). The clearance between the bottom surface of the movable blade 976 and the top surface of the substrate 902 is referenced as δZ 971. The clearance is specified to be large enough to avoid unintentional contact between the movable blade and the substrate and small enough to avoid excessive leakage of the light beam 940 to the peripheral region 910.

In an embodiment, the post 972 is mounted on a stage that can translate along the Z_{S}-axis. The stage is driven by a drive motor, which is controlled by a controller; the controller can be a computer-based controller. To accommodate substrates of different thicknesses, the movable blade can be raised to avoid unintentional contact between the movable blade and the substrate and then lowered to the desired height.

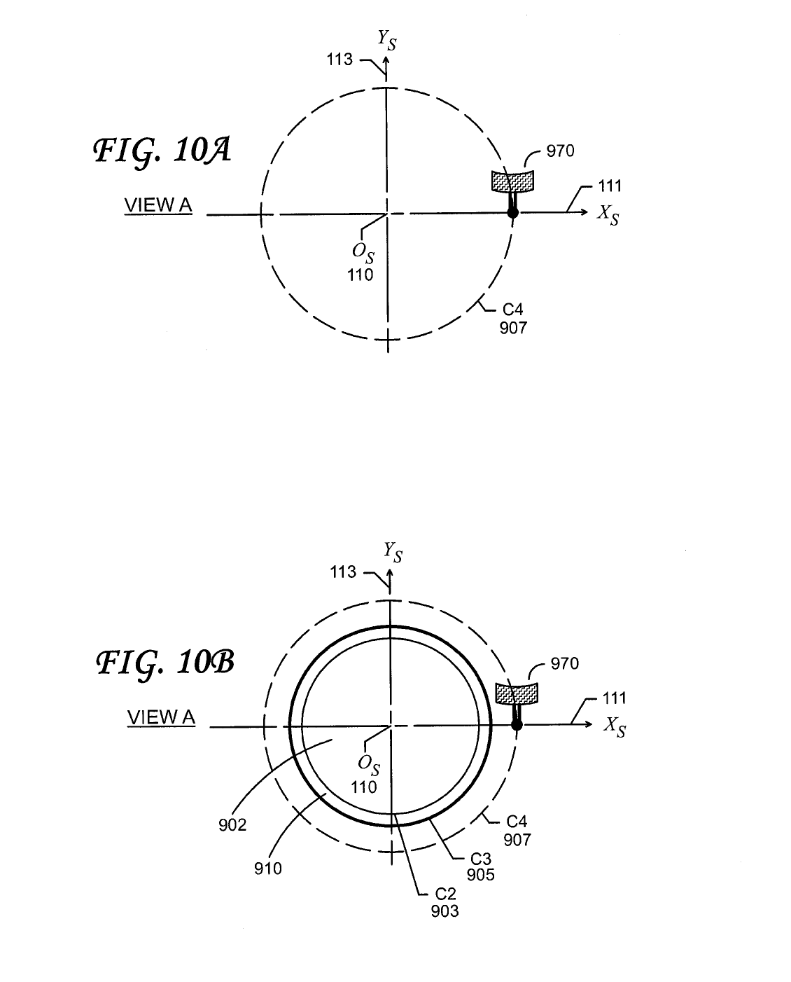

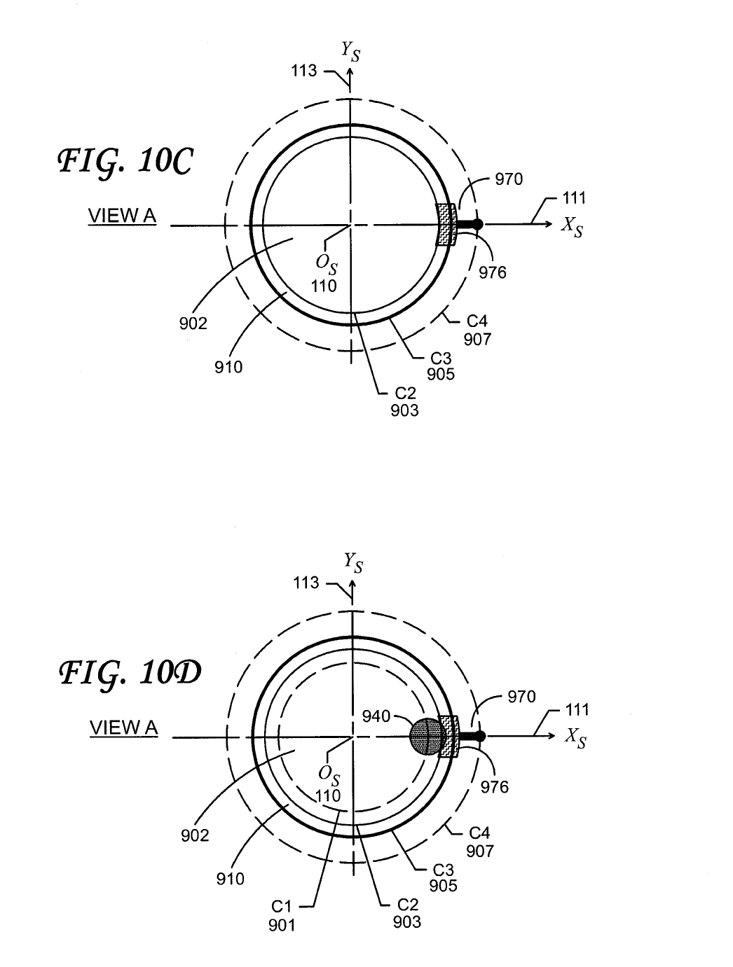

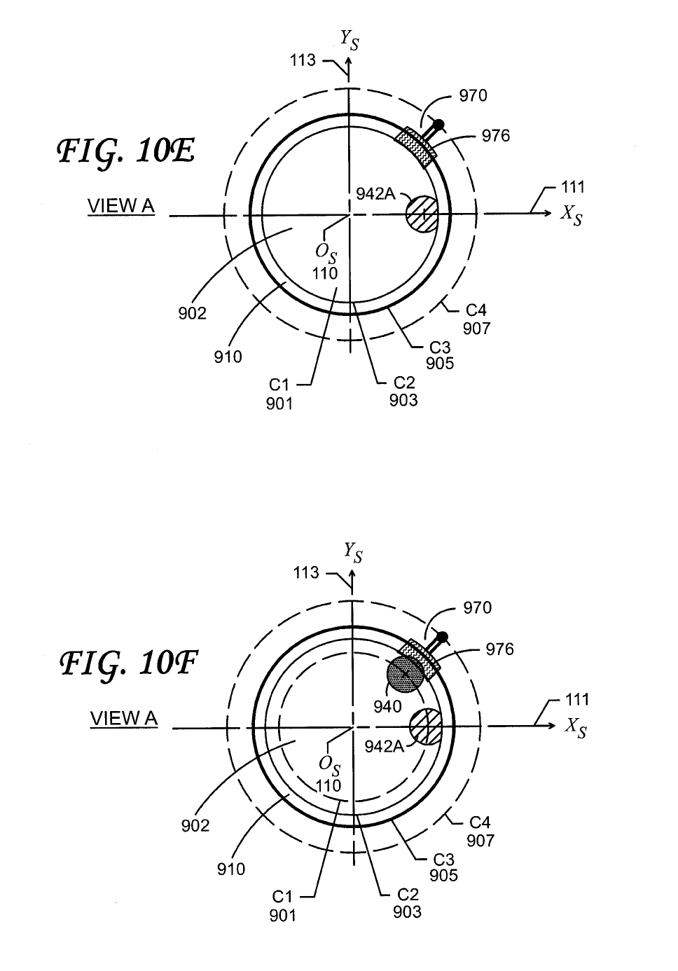

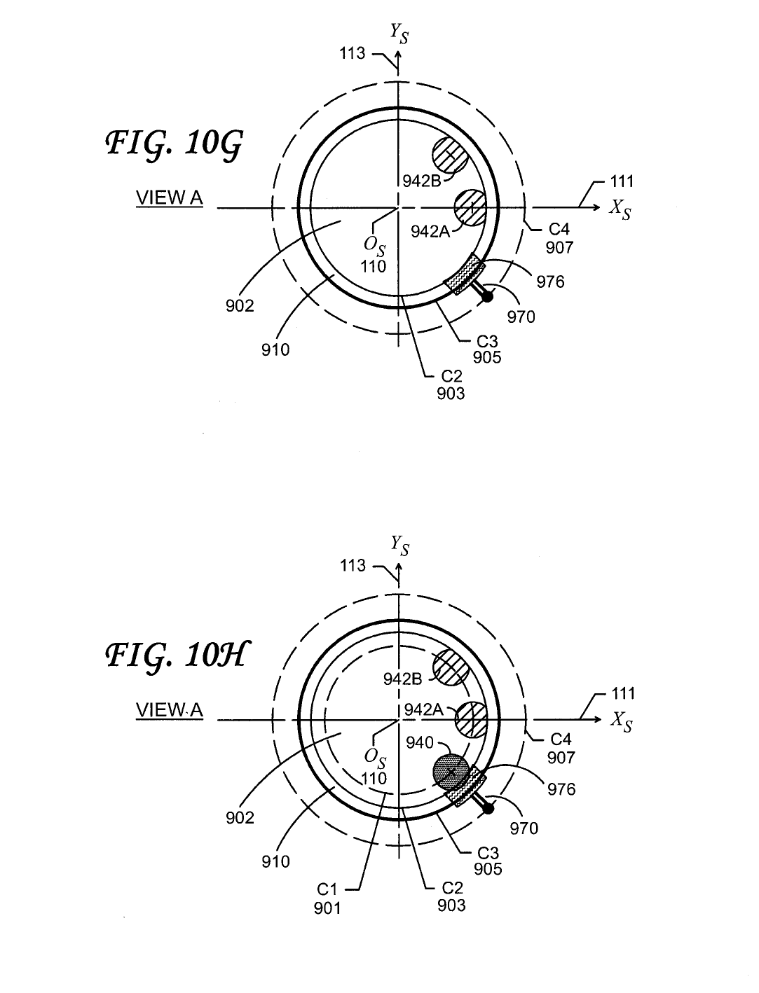

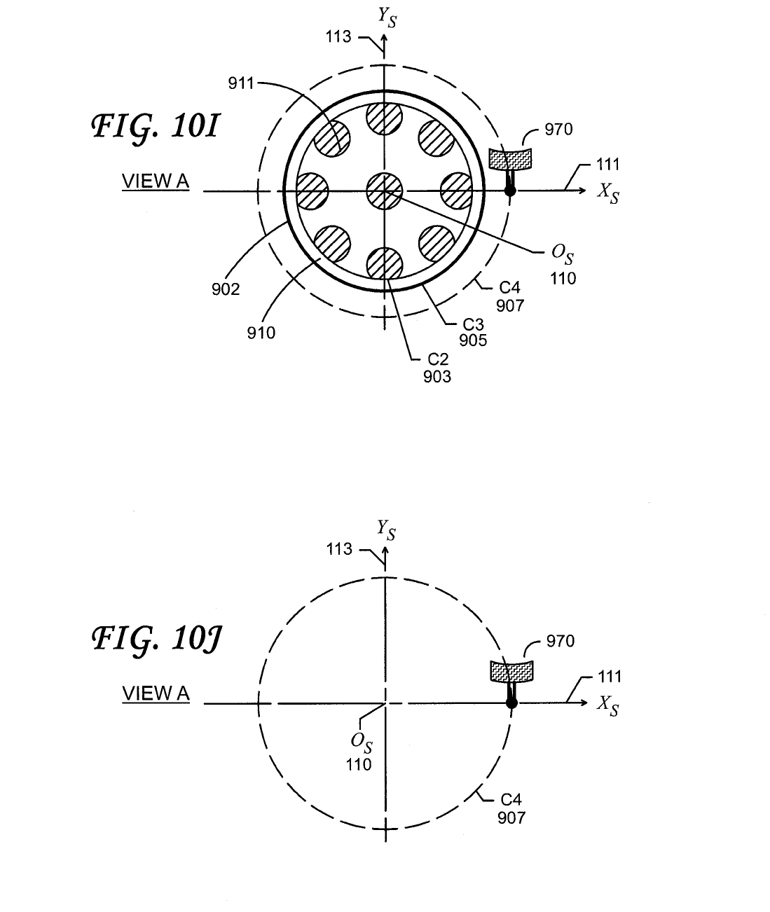

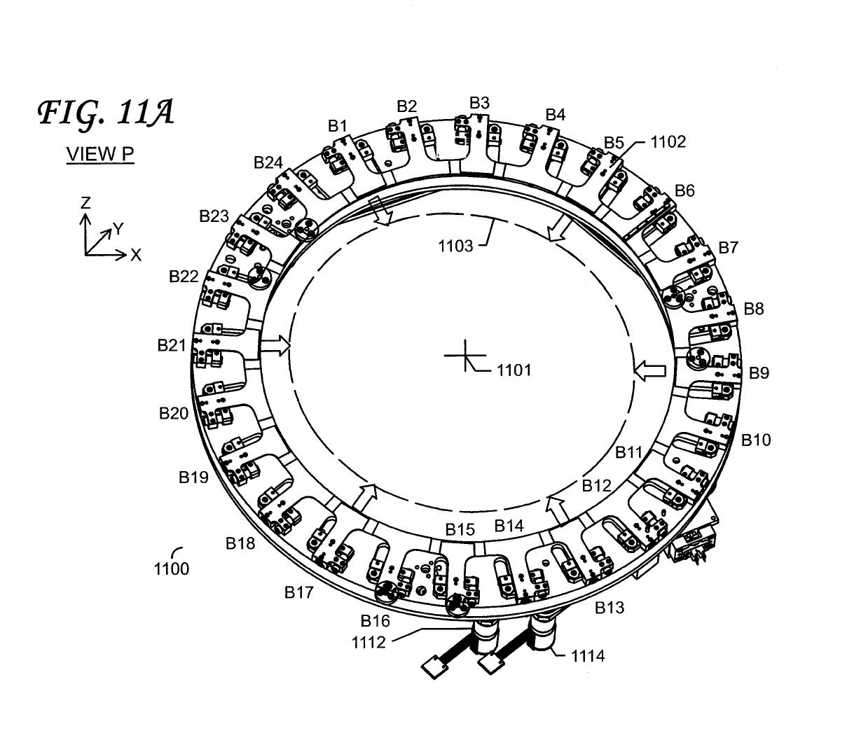

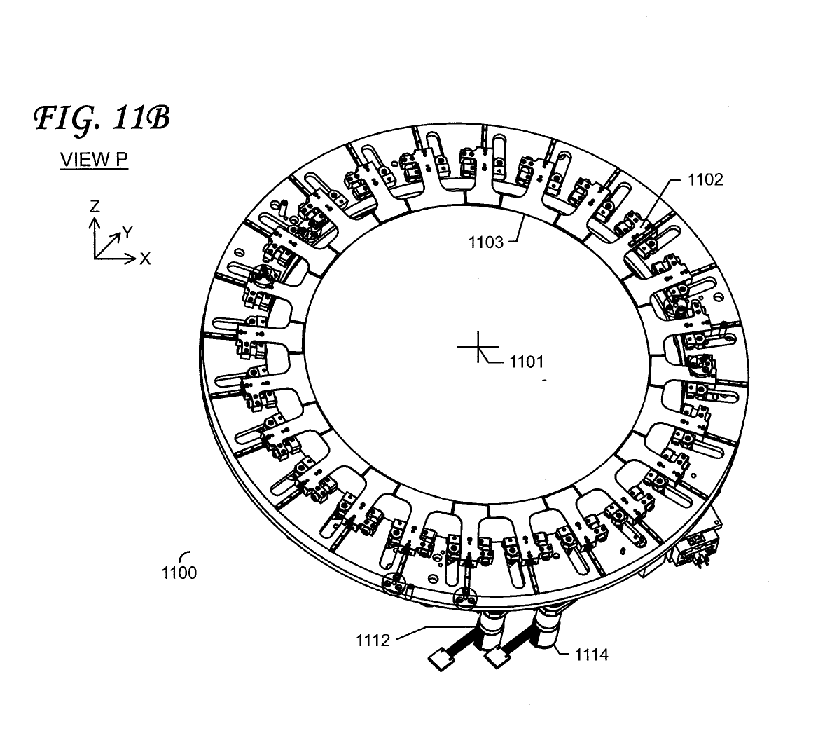

FIG. 10A-FIG. 10J (View A) show a sequence of processing steps with the circular substrate 902 and the movable blade assembly 970. In FIG. 10A, the movable blade assembly 970 is shown in the retracted mode at a first position along the X_{S}-Y_{S} plane. In FIG. 10B, the substrate 902 is inserted. In FIG. 10C, the movable blade 976 is deployed; that is, the movable blade 976 is rotated to cover a first portion of the peripheral region 910. In FIG. 10D, a first position of the substrate 902 is aligned with the projection system 208 (FIG. 2A), and a first portion of the substrate 902 is exposed to the light beam 940 (indicated by dotted hatching). In FIG. 10D, the light beam 940 is illustrated with a circular profile. In general, the profile can have an arbitrary geometry; for example, a rectangular profile is common in some applications. The movable blade 976 covers a first portion of the peripheral region 910 adjacent to the light beam 940.

In FIG. 10E, the region 942A (indicated by diagonal hatching) represents the first portion of the substrate 902 that was exposed to light. The movable blade assembly 970 is moved to a second position, and the movable blade 976 is rotated to a cover a second portion of the peripheral region 910. In FIG. 10F, a second position of the substrate 902 is aligned with the projection system 208, and a second portion of the substrate 902 is exposed to the light beam 940 (indicated by dotted hatching). The movable blade 976 covers a second portion of the peripheral region 910 adjacent to the light beam 940.

In FIG. 100, the region 942B (indicated by diagonal hatching) represents the second portion of the substrate 902 that was exposed to light. The movable blade assembly 970 is moved to a third position, and the movable blade 976 is rotated to a cover a third portion of the peripheral region 910. In FIG. 10H, a third position of the substrate 902 is aligned with the projection system 208, and a third portion of the substrate 902 is exposed to the light beam 940 (indicated by dotted hatching). The movable blade 976 covers a third portion of the peripheral region 910 adjacent to the light beam 940.

In FIG. 10I, the imaging process has been completed. The region 911 refers to the collective set of regions (indicated by diagonal hatching) of the substrate 902 that was exposed to light. The movable blade assembly 970 has moved back to the first position, and the movable blade 976 has been retracted. In FIG. 10J, the substrate 902 has been removed, and the movable blade assembly 970 is ready to accept a new substrate.

In the process described in FIG. 10A-FIG. 10J, the movable blade is retracted by rotating the movable blade: the post is positioned at a constant radius from O_{S}, and the movable blade is swung out of the way such that it clears the substrate. In other embodiments, the movable blade is retracted by translating the entire movable blade assembly sufficiently far from the substrate such that the movable blade clears the substrate, regardless of the rotation angle of the movable blade. The movable blade can also be retracted by a combination of translating the entire movable blade assembly and rotating the movable blade such that the movable blade clears the substrate. In other embodiments, the movable blade can be retracted by tilting the post (such that the post is not orthogonal to the plane of the substrate).

In FIG. 10-FIG. 10J, the steps were described sequentially. Some steps can be done simultaneously. For example, the following steps can be performed simultaneously: the substrate can be moved to align a new position of the substrate with the projection system, the movable blade assembly can be moved to a new position, and the movable blade can be rotated into a new orientation.

The movable blade assembly 970 can be mounted on the substrate stage 222 (FIG. 2A) or mounted separately from the substrate stage. Motor drives can be used to position the post 972 along the reference circle C4 907 and to rotate the movable blade about the pivot axis. In this instance, a rotary drive can be used to position the post 972 along the reference circle C4 907; however, an X-Y drive can also be used. Cam drive systems can also be used. The motor drives can be controlled by a controller, which can be a computer-based controller. The computer-based controller can synchronize operation of the substrate edge protection device with the overall operation of the lithographic projection system 200A (FIG. 2A) to perform the processes previously described in FIG. 10A-FIG. 10J.

As discussed above, the movable blade assembly 970 is not restricted to travel around the circle C4 907. It can move around an arbitrary path to accommodate various substrate geometries (for example, an X-Y drive can be used). In some instances, the movable blade does not need to rotate about a pivot axis. For example, consider the rectangular substrates shown in FIG. 3A-FIG. 3C. Portions of the peripheral regions can be sequentially protected from light exposure by a movable blade covering a portion of the peripheral region. The movable blade can be attached to a non-rotating post, and the post can travel along a rectangular path adjacent to the outer periphery of the substrate, at a specified distance from the outer periphery of the substrate. The movable blade assembly can be retracted to allow insertion and removal of the substrate by translating the movable blade assembly sufficiently far from the substrate such that the movable blade clears the substrate.

Multiple movable single-blade assemblies can be used to improve throughput (by reducing the required travel distance). For example, if the substrate has a rectangular geometry, four movable single-blade assemblies can be used, one along each edge. Multiple movable single-blade assemblies can also be used for lithographic systems with multiple light beams.

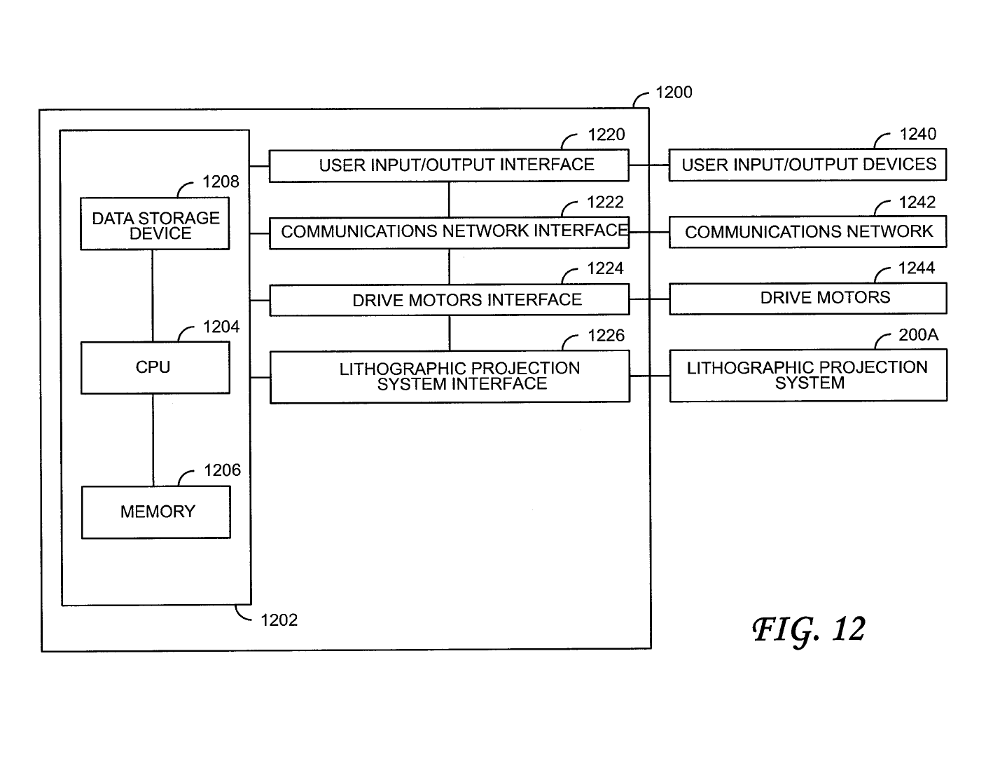

An embodiment of a controller 1200 is shown in FIG. 12. One skilled in the art can construct the controller 1200 from various combinations of hardware, firmware, and software. One skilled in the art can construct the controller 1200 from various electronic components, including one or more general purpose processors (such as microprocessors), one or more digital signal processors, one or more application-specific integrated circuits (ASICs), and one or more field-programmable gate arrays (FPGAs).

The controller 1200 includes a computer 1202, which includes a processor [referred to as the central processing unit (CPU)] 1204, memory 1206, and a data storage device 1208. The data storage device 1208 includes at least one persistent, non-transitory, tangible computer readable medium, such as non-volatile semiconductor memory, a magnetic hard drive, or a compact disc read only memory.

The controller 1200 further includes a user input/output interface 1220, which interfaces the computer 1202 to the user input/output devices 1240. Examples of the user input/output devices 1240 include a keyboard, a mouse, a local access terminal, and a video display. Data, including computer executable code, can be transferred to and from the computer 1202 via the user input/output interface 1220. The computer 1202 can also communicate with other system components (such as components of a lithographic projection system) via the user input/output interface 1220.

The controller 1200 further includes a communications network interface 1222, which interfaces the computer 1202 with a communications network 1242. Examples of the communications network 1242 include a local area network and a wide area network. A user can access the computer 1202 via a remote access terminal (not shown) communicating with the communications network 1242. Data, including computer executable code, can be transferred to and from the computer 1202 via the communications network interface 1222. The computer 1202 can also communicate with other system components (such as components of a lithographic projection system) via the communications network 1242.

The controller 1200 further includes a drive motors interface 1224, which interfaces the computer 1202 with one or more drive motors 1244. The drive motor 1114 (FIG. 11D) is one example of the drive motor 1244. The controller issues a control command or a control signal that causes electrical power to be supplied to a drive motor and that causes the drive motor to generate a drive force.

The controller 1200 further includes a lithographic projection system interface 1226, which interfaces the computer 1202 with, for example, the lithographic projection system 200A. For example, the computer 1202 can communicate with a controller for the substrate stage 222 and a controller for the light source 202 to perform a sequence of operations, such as that described above in reference to FIG. 6A-FIG. 6F or FIG. 10A-FIG. 10J.

As is well known, a computer operates under control of computer software, which defines the overall operation of the computer and applications. The CPU 1204 controls the overall operation of the computer and applications by executing computer program instructions that define the overall operation and applications. The computer program instructions can be stored in the data storage device 1208 and loaded into the memory 1206 when execution of the program instructions is desired. Control algorithms, such as control algorithms for controlling operation of a substrate edge protection device can defined by computer program instructions stored in the memory 1206 or in the data storage device 1208 (or in a combination of the memory 1206 and the data storage device 1208) and controlled by the CPU 2104 executing the computer program instructions. For example, the computer program instructions can be implemented as computer executable code programmed by one skilled in the art to perform algorithms. Accordingly, by executing the computer program instructions, the CPU 1204 executes the control algorithms for a sequence of operations, such as that described above in reference to FIG. 6A-FIG. 6F or FIG. 10A-FIG. 10J.

In the lithographic projection system 200A (FIG. 2A), the substrate edge protection device 230A is positioned such that the one or movable blades 232A are positioned closely above the surface of the substrate 210. In other embodiments, a substrate edge protection device is placed at other positions along the optical path.

Refer to FIG. 2C. The lithographic projection system 200B is similar to the lithographic projection system 200A (FIG. 2A) except that the substrate edge protection device 230B is positioned such that the one or movable blades 232B are positioned closely below the projection system 208. The one or more movable blades 232B intercept a peripheral portion of the light 205A. The remaining light 215B is focussed into the image 207B, which is projected onto the surface of the substrate 210 coated with photoresist. Characteristics of the image 207B are discussed below.

Refer to FIG. 2D. The lithographic projection system 200C is similar to the lithographic projection system 200A (FIG. 2A) except that the substrate edge protection device 230C is positioned such that the one or movable blades 232C are positioned between the reticle 204 and the projection system 208. The one or more movable blades 232C intercept a peripheral portion of the light 203A. The remaining light 213C is received by the projection system 208, which focusses the light 205C into the image 207C, which is projected onto the surface of the substrate 210 coated with photoresist. Characteristics of the image 207C are discussed below.

Refer to FIG. 2E. The lithographic projection system 200D is similar to the lithographic projection system 200A (FIG. 2A) except that the substrate edge protection device 230D is positioned such that the one or movable blades 232D are positioned between the light source 202 and the reticle 204. The one or more movable blades 232D intercept a peripheral portion of the light 201A. The remaining light 211 is received by the relay lens 240, which focusses the light 217D to form an image of a portion of the one or movable blades 232D onto the reticle 204. [In some embodiments, the relay lens 240 is not used.] The light 203D transmitted through the reticle 204 is received by the projection system 208, which focusses the light 205D into the image 207D, which is projected onto the surface of the substrate 210 coated with photoresist. Characteristics of the image 207D are discussed below.

FIG. 2F-FIG. 2H show examples of the profiles of the images projected onto the surface of the substrate.

Refer to FIG. 2F. The image field 207P1 represents the image field of the projected image 207A (FIG. 2A) in the absence of the substrate edge protection device 230A. The boundary of the image field is represented by the circle 272. As described above, the shape of the boundary is arbitrary. The interior of the image field is denoted 280A, indicated by dotted hatching. For simplicity, the image of the reticle pattern is not shown, and the interior of the image field is represented by dotted hatching. Since the full image field is illuminated, the substrate edge protection device 230A is used to cover the portions of the peripheral region of the surface of the substrate that need to be protected, as described above.

Refer to FIG. 2G. The image field 207P2 represents the image field of the projected image 207B (FIG. 2C), the projected image 207C (FIG. 2D), or the projected image 207D (FIG. 2E), when the substrate edge protection device 230B, the substrate edge protection device 230C, or the substrate edge protection device 230D, respectively, is used to pre-process the image of the reticle before it is projected onto the surface of the substrate. In this example, the substrate edge protection device is a multi-blade device used to protect the peripheral region of a circular substrate. The boundary of the image field is represented by the circle 272, as in FIG. 2F. The interior of the image field is denoted 280B, indicated by dotted hatching. The peripheral region of the image field, represented by the black circular annular region 274, has been occluded by the multiple movable blades of the substrate edge protection device. If the black circular annular region overlaps a portion of the peripheral region of the surface of the substrate, that portion of the peripheral region will not be exposed to light.

For large substrates, the dimensions of the image field can be substantially smaller than the dimensions of the substrate. Therefore, the blade dimensions for covering the entire peripheral region of the projected image field can be substantially less than the blade dimensions for covering the entire peripheral region of the substrate.

Refer to FIG. 2H. The image field 207P3 represents the image field of the projected image 207B (FIG. 2C), the projected image 207C (FIG. 2D), or the projected image 207D (FIG. 2E), when the substrate edge protection device 230B, the substrate edge protection device 230C, or the substrate edge protection device 230D, respectively, is used to pre-process the image of the reticle before it is projected onto the surface of the substrate. In this example, the substrate edge protection device is a single-blade device used to protect a portion of the peripheral region of a circular substrate. The boundary of the image field is represented by the circle 272, as in FIG. 2F. The interior of the image field is denoted 280C, indicated by dotted hatching. A portion of the peripheral region of the image field, represented by the black region 276 (a portion of a circular annular region), has been occluded by the single movable blade of the substrate edge protection device. If the black region 276 overlaps a portion of the peripheral region of the surface of the substrate, that portion of the peripheral region will not be exposed to light.

The movable blade moves physically with respect to the projected image field, not with respect to the substrate. Movement of the movable blade is coordinated with movement of the substrate such that that apparent movement of the movable blade is around the periphery of the substrate. For large substrates, the dimensions of the image field can be substantially smaller than the dimensions of the substrate. Therefore, the blade travel for covering the entire peripheral region of the projected image field can be substantially less than the blade travel for covering the entire peripheral region of the substrate.

In general, the substrate edge protection device 230B, the substrate edge protection device 230C, and the substrate edge protection device 230D have one or more movable blades that partition the image field of the projected image into an occluded image field (no light) and a non-occluded image field (with light containing an image of the pattern on the reticle). Embodiments of the substrate edge protection device 230A described above can be adapted as embodiments of the substrate edge protection device 230B, the substrate edge protection device 230C, and the substrate edge protection device 230D.

The foregoing Detailed Description is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention.

1. An apparatus for protecting a portion of a peripheral region of a photoresist-coated surface of a substrate from light exposure, the apparatus comprising:
a movable blade; and
a drive assembly operably coupled to the movable blade;
wherein:
in response to at least one first drive force generated by the drive assembly, the movable blade translates such that the movable blade is disposed above the portion of the peripheral region; and
in response to at least one second drive force generated by the drive assembly, the movable blade translates such that the movable blade is not disposed above the portion of the peripheral region.

2. The apparatus of claim 1, wherein:
the drive assembly comprises at least one drive motor; and
the apparatus further comprises a controller;
wherein:
in response to a first control command or a first control signal generated by the controller, the at least one drive motor generates the at least one first drive force; and
in response to a second control command or a second control signal generated by the controller, the at least one drive motor generates the at least one second drive force.

3. The apparatus of claim 1, wherein:
the portion of the peripheral region is a first portion of the peripheral region; and
in response to at least one third drive force generated by the drive assembly, the movable blade translates such that the movable blade is disposed above a second portion of the peripheral region.

4. A method for lithographic processing of a photoresist-coated surface of a substrate, wherein the photoresist-coated surface comprises a peripheral region and an interior region, the method comprising the steps of:
translating a movable blade such that the movable blade is disposed above a first portion of the peripheral region;
exposing a first portion of the interior region to light, wherein the first portion of the interior region is adjacent to the first portion of the peripheral region;
translating the movable blade such that the movable blade is disposed above a second portion of the peripheral region; and
exposing a second portion of the interior region to light, wherein the second portion of the interior region is adjacent to the second portion of the peripheral region.

5. The method of claim 4, wherein:
the movable blade is operably coupled to at least one drive motor controlled by a controller;
the step of translating the movable blade such that the movable blade is disposed above a first portion of the peripheral region comprises the steps of:
generating, with the controller, a first control command or a first control signal;
in response to the first control command or the first control signal, supplying electrical power to the at least one drive motor to generate at least one first drive force; and
in response to the at least one first drive force, translating the movable blade such that the movable blade is disposed above the first portion of the peripheral region; and
the step of translating the movable blade such that the movable blade is disposed above a second portion of the peripheral region comprises the steps of:
generating, with the controller, a second control command or a second control signal;
in response to the second control command or the second control signal, supplying electrical power to the at least one drive motor to generate at least one second drive force; and
in response to the at least one second drive force, translating the movable blade such that the movable blade is disposed above the second portion of the peripheral region.

6. The method of claim 4, further comprising the step of:
translating the movable blade such that the movable blade is not disposed above any portion of the peripheral region.

7. An apparatus for protecting a portion of a peripheral region of a photoresist-coated surface of a substrate from light exposure, the apparatus comprising:
a movable and rotatable blade; and
a drive assembly operably coupled to the movable and rotatable blade;
wherein:
in response to at least one first drive force generated by the drive assembly, the movable and rotatable blade performs at least one action selected from the group consisting of translation and rotation, such that the movable and rotatable blade is disposed above the portion of the peripheral region; and
in response to at least one second drive force generated by the drive assembly, the movable and rotatable blade performs at least one action selected from the group consisting of translation and rotation, such that the movable and rotatable blade is not disposed above the portion of the peripheral region.

8. The apparatus of claim 7, wherein:
the drive assembly comprises at least one drive motor; and
the apparatus further comprises a controller;
wherein:
in response to a first control command or a first control signal generated by the controller, the at least one drive motor generates the at least one first drive force; and
in response to a second control command or a second control signal generated by the controller, the at least one drive motor generates the at least one second drive force.

9. The apparatus of claim 7, wherein:
the portion of the peripheral region is a first portion of the peripheral region; and
in response to at least one third drive force generated by the drive assembly, the movable and rotatable blade performs at least one action selected from the group consisting of translation and rotation, such that the movable and rotatable blade is disposed above a second portion of the peripheral region.

10. The apparatus of claim 7, wherein:
the movable and rotatable blade comprises a blade operably coupled to a post;
the post is movable along a plane;
the post has a longitudinal axis orthogonal to the plane; and
the post is rotatable about the longitudinal axis.

11. A method for lithographic processing of a photoresist-coated surface of a substrate, wherein the photoresist-coated surface comprises a peripheral region and an interior region, the method comprising the steps of:
disposing a movable and rotatable blade above a first portion of the peripheral region, wherein disposing comprises performing at least one action selected from the group consisting of translation and rotation;
exposing a first portion of the interior region to light, wherein the first portion of the interior region is adjacent to the first portion of the peripheral region;
disposing the movable and rotatable blade such that the movable and rotatable blade is disposed above a second portion of the peripheral region, wherein disposing comprises performing at least one action selected from the group consisting of translation and rotation; and
exposing a second portion of the interior region to light, wherein the second portion of the interior region is adjacent to the second portion of the peripheral region.

12. The method of claim 11, wherein:
the movable and rotatable blade is operably coupled to at least one drive motor controlled by a controller;
the step of disposing the movable and rotatable blade such that the movable and rotatable blade is disposed above a first portion of the peripheral region comprises the steps of:
generating, with the controller, a first control command or a first control signal;
in response to the first control command or the first control signal, supplying electrical power to the at least one drive motor to generate at least one first drive force; and
in response to the at least one first drive force, disposing the movable and rotatable blade such that the movable and rotatable blade is disposed above the first portion of the peripheral region; and
the step of disposing the movable and rotatable blade such that the movable and rotatable blade is disposed above a second portion of the peripheral region comprises the steps of:
generating, with the controller, a second control command or a second control signal;
in response to the second control command or the second control signal, supplying electrical power to the at least one drive motor to generate at least one second drive force; and
in response to the at least one second drive force, disposing the movable and rotatable blade such that the movable and rotatable blade is disposed above the second portion of the peripheral region.

13. The method of claim 11, further comprising the step of:
disposing the movable and rotatable blade such that the movable and rotatable blade is not disposed above any portion of the peripheral region, wherein disposing comprises performing at least one action selected from the group consisting of translation and rotation.

14. A lithographic projection system comprising:
a light source configured to transmit first light;
a reticle having a pattern, wherein the reticle is configured to:
receive the first light; and
transmit second light having the pattern;
a movable substrate stage configured to receive a substrate having a photoresist-coated surface;
a projection system configured to:
receive the second light; and
project an image of the pattern onto the photoresist-coated surface of the substrate, wherein the photoresist-coated surface comprises a peripheral region and an interior region; and
a substrate edge protection device comprising a movable blade, wherein:
the movable blade is configured to partition the projected image into an occluded image field and a non-occluded image field; and
the substrate edge protection device is configured to translate the movable blade such that at least a portion of the occluded image field is projected onto at least a specified portion of the peripheral region and no portion of the non-occluded image field is projected onto at least a specified portion of the peripheral region.

15. The lithographic projection system of claim 14, wherein the substrate edge protection device is disposed between the projection system and the substrate stage.

16. The lithographic projection system of claim 14, wherein the substrate edge protection device is disposed between the reticle and the projection system.

17. The lithographic projection system of claim 14, wherein the substrate edge protection device is disposed between the light source and the reticle.

18. The lithographic projection system of claim 16, further comprising a relay lens disposed between the substrate edge protection device and the reticle.

19. A lithographic projection system comprising:
a light source configured to transmit first light;
a reticle having a pattern, wherein the reticle is configured to:
receive the first light; and
transmit second light having the pattern;
a movable substrate stage configured to receive a substrate having a photoresist-coated surface;
a projection system configured to:
receive the second light;
and project an image of the pattern onto the photoresist-coated surface of the substrate, wherein the photoresist-coated surface comprises a peripheral region and an interior region; and
a substrate edge protection device comprising a movable and rotatable blade, wherein:
the movable and rotatable blade is configured to partition the projected image into an occluded image field and a non-occluded image field; and
the substrate edge protection device is configured to perform at least one action selected from the group consisting of translation of the movable and rotatable blade and rotation of the movable and rotatable blade, such that at least a portion of the occluded image field is projected onto at least a specified portion of the peripheral region and no portion of the non-occluded image field is projected onto at least a specified portion of the peripheral region.

20. The lithographic projection system of claim 19, wherein the substrate edge protection device is disposed between the projection system and the substrate stage.

21. The lithographic projection system of claim 19, wherein the substrate edge protection device is disposed between the reticle and the projection system.

22. The lithographic projection system of claim 19, wherein the substrate edge protection device is disposed between the light source and the reticle.

23. The lithographic projection system of claim 22, further comprising a relay lens disposed between the substrate edge protection device and the reticle.
